(19) United States
(12) Patent Application Publication
(10) Pub. No.: US 2024/0279434 A1
(43) Pub. Date: Aug. 22, 2024

(54) RESIN COMPOSITION, PREPREG, RESIN-COATED FILM, RESIN-COATED METAL FOIL, METAL-CLAD LAMINATE, AND WIRING BOARD

(71) Applicant: PANASONIC INTELLECTUAL PROPERTY MANAGEMENT CO., LTD., Osaka (JP)

(72) Inventors: Shinichi KATSUTA, Fukushima (JP); Tatsuya ARISAWA, Fukushima (JP); Tomohiro HOSI, Fukushima (JP); Tomoyuki ABE, Fukushima (JP)

(73) Assignee: PANASONIC INTELLECTUAL PROPERTY MANAGEMENT CO., LTD., Osaka (JP)

(21) Appl. No.: 18/567,246

(22) PCT Filed: May 23, 2022
(86) PCT No.: PCT/JP2022/021140

§ 371 Date: Dec. 5, 2023

(30) Foreign Application Priority Data
Jun. 8, 2021 (JP) 2021-095998

(51) Int. Cl. C08K 5/523; C08F 290/06; C08G 65/48

(52) U.S. Cl. CPC C08K 5/523; C08F 290/062; C08G 65/485

(57) ABSTRACT

One aspect of the present invention is a resin composition containing a radical-polymerizable compound (A) having a carbon-carbon unsaturated double bond in a molecule and a phosphoric acid ester compound (B) having an alicyclic hydrocarbon structure in a molecule.

### TECHNICAL FIELD

The present invention relates to a resin composition, a prepreg, a film with resin, a metal foil with resin, a metal-clad laminate, and a wiring board.

### BACKGROUND ART

In various electronic devices, mounting technologies such as higher integration of semiconductor devices to be mounted, higher wiring density, and multi-layering have rapidly progressed along with an increase in the amount of information processed. In addition, wiring boards used in various electronic devices are required to be, for example, high-frequency compatible wiring boards such as a millimeter-wave radar board for in-vehicle use. Substrate materials for forming insulating layers of wiring boards used in various electronic devices are required to have excellent low dielectric properties such as a low relative dielectric constant and a low dielectric loss tangent in order to increase a signal transmission speed and to decrease signal transmission loss.

The wiring board is also required to have excellent flame retardancy. In this respect, a halogen-based flame retardant such as a bromine-based flame retardant and a halogen-containing compound such as a halogen-containing epoxy resin have been compounded in a resin composition used as a substrate material in many cases. A cured product of a resin composition containing such a halogen-containing compound contains a halogen. When this cured product is combusted, there is a possibility that a harmful substance such as hydrogen halide may be generated, and a concern of adverse effects on the human body, the natural environment, and the like is pointed out. Under such circumstances, a substrate material and the like are required not to contain halogen, i.e., a so-called halogen-free material is demanded.

In order to realize such halogen-free conversion, it is conceivable to use a resin composition containing a halogen-free flame retardant as a substrate material. As such a resin composition containing the halogen-free flame retardant, for example, a curable resin composition described in Patent Literature 1 can be mentioned.

Patent Literature 1 describes a curable resin composition containing 100 parts by weight of an alicyclic olefin polymer, 1 to 100 parts by weight of a curing agent, 10 to 50 parts by weight of a salt of a basic nitrogen-containing compound and phosphoric acid, and 0.1 to 40 parts by weight of a condensed phosphoric acid ester, and having a phosphorus element content of 1.5% by weight or more. Patent Literature 1 discloses that the curable resin composition is excellent in moisture resistance, flame retardancy, surface smoothness, insulating properties, and crack resistance, and hardly generates harmful substances in burning.

Wiring boards used in various electronic devices are also required to be hardly affected by changes in the external environment. Specifically, the wiring board is also required to have excellent interlayer adhesion such that delamination does not occur even in an environment with relatively high humidity. Hence, substrate materials for forming insulating layers of wiring boards are required to afford a cured product that maintains excellent interlayer adhesion even upon adsorption of moisture.

Wiring boards used in various electronic devices are also required to be hardly affected by reflow and the like during mounting. Substrate materials for forming insulating layers of wiring boards are required to afford cured products exhibiting superior heat resistance such as a high glass transition temperature so that the wiring boards can be used without problems, for example, after subjected to reflow processing as well. It is also required that insulating layers equipped in wiring board are not deformed by reflow or the like. Since this deformation is suppressed when the glass transition temperature of the insulating layers is high, the substrate materials for forming insulating layers of wiring boards are required to afford cured products exhibiting superior heat resistance such as a high glass transition temperature. As described above, the substrate materials for forming insulating layers of the wiring boards are required to afford cured products having high glass transition temperatures in order to obtain wiring boards exhibiting excellent reliability in a wide temperature range as well.

### CITATION LIST

### Patent Literature

Patent Literature 1: WO 2008/047583 A

### SUMMARY OF INVENTION

The present invention has been made in view of such circumstances, and an object thereof is to provide a resin composition, which affords a cured product having a low relative dielectric constant and a low dielectric loss tangent, being excellent in flame retardancy and interlayer adhesion, and having a high glass transition temperature. Another object of the present invention is to provide a prepreg, a film with resin, a metal foil with resin, a metal-clad laminate, and a wiring board, which are obtained using the resin composition.

One aspect of the present invention is a resin composition containing a radical-polymerizable compound (A) having a carbon-carbon unsaturated double bond in a molecule and a phosphoric acid ester compound (B) having an alicyclic hydrocarbon structure in a molecule.

### BRIEF DESCRIPTION OF DRAWINGS

FIG. 1 is a schematic cross-sectional view showing an example of a prepreg according to an embodiment of the present invention.

FIG. 2 is a schematic cross-sectional view showing an example of a metal-clad laminate according to an embodiment of the present invention.

FIG. 3 is a schematic cross-sectional view showing an example of a wiring board according to an embodiment of the present invention.

FIG. 4 is a schematic cross-sectional view showing an example of a metal foil with resin according to an embodiment of the present invention.

FIG. 5 is a schematic cross-sectional view showing an example of a film with resin according to an embodiment of the present invention.

### DESCRIPTION OF EMBODIMENTS

Studies by the present inventors have found that in a resin composition containing a halogen-free flame retardant, such as the curable resin composition described in Patent Literature 1, interlayer adhesion may be reduced or the glass transition temperature may be lowered depending on the type of the flame retardant. For example, it has been found that when the condensed phosphoric acid ester described in Patent Literature 1 is used as the flame retardant, the interlayer adhesion is reduced, and the glass transition temperature is relatively low.

The present inventors have found out that the objects are achieved by the present invention described below as a result of extensive studies.

Hereinafter, embodiments according to the present invention will be described, but the present invention is not limited thereto.

### [Resin Composition]

A resin composition according to an embodiment of the present invention is a resin composition containing a radical-polymerizable compound (A) having a carbon-carbon unsaturated double bond in a molecule and a phosphoric acid ester compound (B) having an alicyclic hydrocarbon structure in a molecule. By curing the resin composition having such a configuration, a cured product is obtained which has a low relative dielectric constant and a low dielectric loss tangent, is in excellent in flame retardancy and interlayer adhesion, and has a high glass transition temperature. It is considered that a cured product having a low relative dielectric constant, a low dielectric loss tangent, and a high glass transition temperature can be obtained by curing the radical-polymerizable compound (A) contained in the resin composition. When the phosphoric acid ester compound (B) is contained in the resin composition, the phosphoric acid ester compound (B) is also contained in the cured product of the resin composition. It is considered that when the phosphoric acid ester compound (B) is contained in the cured product of the resin composition, the flame retardancy can be enhanced while suppressing an increase in relative dielectric constant and dielectric loss tangent and suppressing a decrease in glass transition temperature. From these facts, it is considered that a cured product is obtained which has a low relative dielectric constant and a low dielectric loss tangent, is in excellent in flame retardancy and interlayer adhesion, and has a high glass transition temperature.

### (Radical-Polymerizable Compound (A))

The radical-polymerizable compound (A) is not particularly limited as long as it is a radical-polymerizable compound having a carbon-carbon unsaturated double bond in the molecule. The radical-polymerizable compound (A) preferably contains, for example, a polyphenylene ether compound (A1) having a carbon-carbon unsaturated double bond in the molecule, and more preferably contains the polyphenylene ether compound (A1) and the radical-polymerizable compound (another radical-polymerizable compound) (A2) other than the polyphenylene ether compound (A1). Examples of the other radical-polymerizable compound (A2) include a curing agent of the polyphenylene ether compound (A1).

The polyphenylene ether compound (A1) is not particularly limited as long as it is a polyphenylene ether compound having a carbon-carbon unsaturated double bond in the molecule. Examples of the polyphenylene ether compound (A1) include a polyphenylene ether compound having a carbon-carbon unsaturated double bond at the terminal, and more specific examples thereof include a polyphenylene ether compound having a substituent having a carbon-carbon unsaturated double bond at the molecular terminal such as a modified polyphenylene ether compound of which the terminal is modified with a substituent having a carbon-carbon unsaturated double bond.

Examples of the substituent having a carbon-carbon unsaturated double bond include a group represented by the following Formula (3) and a group represented by the following Formula (4). In other words, examples of the polyphenylene ether compound (A1) include a polyphenylene ether compound having at least one selected from a group represented by the following Formula (3) or a group represented by the following Formula (4) in the molecule.

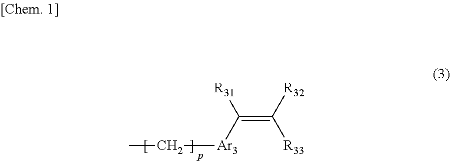

In Formula (3), p represents 0 to 10. Ar₃ represents an arylene group. R₃₁ to R₃₃ are independent from one another. That is, R₃₁ to R₃₃ may be the same group as or different groups from each other. R₃₁ to R₃₃ represent a hydrogen atom or an alkyl group. In a case where p in Formula (3) is 0, it indicates that Ar₃ is directly bonded to polyphenylene ether.

The arylene group is not particularly limited. Examples of this arylene group include a monocyclic aromatic group such as a phenylene group and a polycyclic aromatic group that is polycyclic aromatic such as a naphthalene ring. This arylene group also includes a derivative in which a hydrogen atom bonded to an aromatic ring is substituted with a functional group such as an alkenyl group, an alkynyl group, a formyl group, an alkylcarbonyl group, an alkenylcarbonyl group, or an alkynylcarbonyl group.

The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

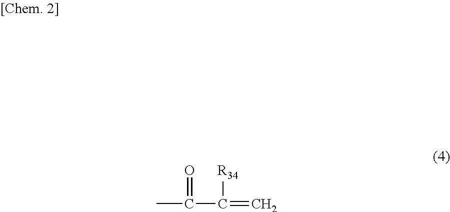

In Formula (4), R₃₄ represents a hydrogen atom or an alkyl group. The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

Examples of the group represented by Formula (3) include a vinylbenzyl group (ethenylbenzyl group) represented by the following Formula (5). Examples of the group represented by Formula (4) include an acryloyl group and a methacryloyl group.

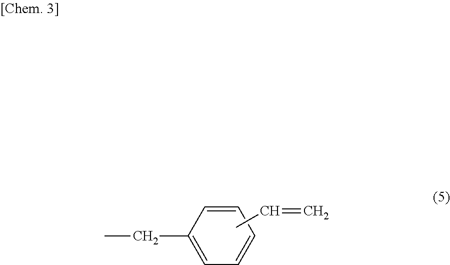

More specific examples of the substituent include vinylbenzyl groups (ethenylbenzyl groups) such as an o-ethenylbenzyl group, a m-ethenylbenzyl group, and a p-ethenylbenzyl group, a vinylphenyl group, an acryloyl group, and a methacryloyl group. The polyphenylene ether compound (A1) may have one substituent or two or more substituents as the substituent. The polyphenylene ether compound (A1) may have, for example, any of an o-ethenylbenzyl group, a m-ethenylbenzyl group, or a p-ethenylbenzyl group, or two or three of these.

The polyphenylene ether compound (A1) has a polyphenylene ether chain in the molecule and preferably has, for example, a repeating unit represented by the following Formula (6) in the molecule.

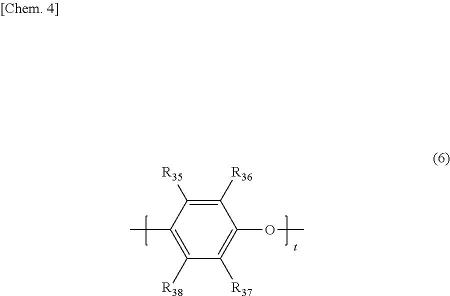

In Formula (6), t represents 1 to 50. R₃₅ to R₃₈ are independent from one another. That is, R₃₅ to R₃₈ may be the same group as or different groups from each other. R₃₅ to R₃₈ each represent a hydrogen atom, an alkyl group, an alkenyl group, an alkynyl group, a formyl group, an alkylcarbonyl group, an alkenylcarbonyl group, or an alkynylcarbonyl group. Among them, each of R₃₅ to R₃₈ is preferably a hydrogen atom and an alkyl group.

Specific examples of each functional group listed in R₃₅ to R₃₈ include the following.

The alkyl group is not particularly limited and is, for example, preferably an alkyl group having 1 to 18 carbon atoms, more preferably an alkyl group having 1 to 10 carbon atoms. Specific examples thereof include a methyl group, an ethyl group, a propyl group, a hexyl group, and a decyl group.

The alkenyl group is not particularly limited and is, for example, preferably an alkenyl group having 2 to 18 carbon atoms, more preferably an alkenyl group having 2 to 10 carbon atoms. Specific examples thereof include a vinyl group, an allyl group, and a 3-butenyl group.

The alkynyl group is not particularly limited and is, for example, preferably an alkynyl group having 2 to 18 carbon atoms, more preferably an alkynyl group having 2 to 10 carbon atoms. Specific examples thereof include an ethynyl group and a prop-2-yn-1-yl group (propargyl group).

The alkylcarbonyl group is not particularly limited as long as it is a carbonyl group substituted with an alkyl group and is, for example, preferably an alkylcarbonyl group having 2 to 18 carbon atoms, more preferably an alkylcarbonyl group having 2 to 10 carbon atoms. Specific examples thereof include an acetyl group, a propionyl group, a butyryl group, an isobutyryl group, a pivaloyl group, a hexanoyl group, an octanoyl group, and a cyclohexylcarbonyl group.

The alkenylcarbonyl group is not particularly limited as long as it is a carbonyl group substituted with an alkenyl group and is, for example, preferably an alkenylcarbonyl group having 3 to 18 carbon atoms, more preferably an alkenylcarbonyl group having 3 to 10 carbon atoms. Specific examples thereof include an acryloyl group, a methacryloyl group, and a crotonoyl group.

The alkynylcarbonyl group is not particularly limited as long as it is a carbonyl group substituted with an alkynyl group and is, for example, preferably an alkynylcarbonyl group having 3 to 18 carbon atoms, more preferably an alkynylcarbonyl group having 3 to 10 carbon atoms. Specific examples thereof include a propioloyl group.

The weight average molecular weight (Mw) and number average molecular weight (Mn) of the polyphenylene ether compound (A1) are not particularly limited, and specifically, are preferably 500 to 5,000, more preferably 800 to 4,000, still more preferably 1,000 to 3,000. Here, the weight average molecular weight and number average molecular weight may be those measured by general molecular weight measurement methods, and specific examples thereof include values measured by gel permeation chromatography (GPC). In a case where the polyphenylene ether compound (A1) has a repeating unit represented by Formula (6) in the molecule, t is preferably a numerical value so that the weight average molecular weight and number average molecular weight of the polyphenylene ether compound is in such a range. Specifically, t is preferably 1 to 50.

When the weight average molecular weight and number average molecular weight of the polyphenylene ether compound (A1) are in the above range, the excellent low dielectric properties of polyphenylene ether are exhibited, and not only the heat resistance of the cured product is superior but also the moldability is excellent. This is considered to be due to the following. When the weight average molecular weight and number average molecular weight of ordinary polyphenylene ether are in the above range, the molecular weight is relatively low, and thus the heat resistance tends to decrease. With regard to this point, it is considered that since the polyphenylene ether compound (A1) has one or more unsaturated double bonds at the terminal, a cured product exhibiting sufficiently high heat resistance is obtained as the curing reaction proceeds. When the weight average molecular weight and number average molecular weight of the polyphenylene ether compound (A1) are in the above range, it is considered that the molecular weight is relatively low and thus the moldability is also excellent. Hence, it is considered that such a polyphenylene ether compound not only imparts superior heat resistance to the cured product but also exhibits excellent moldability.

In the polyphenylene ether compound (A1), the average number of the substituents (number of terminal functional groups) at the molecular terminal per one molecule of the polyphenylene ether compound is not particularly limited. Specifically, the average number is preferably 1 to 5, more preferably 1 to 3, still more preferably 1.5 to 3. When the number of terminal functional groups is too small, sufficient heat resistance of the cured product tends to be hardly attained. When the number of terminal functional groups is too large, the reactivity is too high and, for example, troubles such as deterioration in the storage stability of the resin composition or deterioration in the fluidity of the resin composition may occur. In other words, when such a polyphenylene ether compound is used, for example, molding defects such as generation of voids at the time of multilayer molding occur by insufficient fluidity and the like and a problem of moldability that a highly reliable printed wiring board is hardly obtained may occur.

The number of terminal functional groups in the polyphenylene ether compound includes a numerical value expressing the average value of the substituents per one molecule of all the polyphenylene ether compounds present in 1 mole of the polyphenylene ether compound. This number of terminal functional groups can be determined by, for example, measuring the number of hydroxyl groups remaining in the obtained polyphenylene ether compound and calculating the number of hydroxyl groups decreased from the number of hydroxyl groups in the polyphenylene ether before having (before being modified with) the substituent. The number of hydroxyl groups decreased from the number of hydroxyl groups in the polyphenylene ether before being modified is the number of terminal functional groups. Moreover, with regard to the method for measuring the number of hydroxyl groups remaining in the polyphenylene ether compound, the number of hydroxyl groups can be determined by adding a quaternary ammonium salt (tetraethylammonium hydroxide) to be associated with a hydroxyl group to a solution of the polyphenylene ether compound and measuring the UV absorbance of the mixed solution.

The intrinsic viscosity of the polyphenylene ether compound (A1) is not particularly limited. Specifically, the intrinsic viscosity may be 0.03 to 0.12 dl/g, and is preferably 0.04 to 0.11 dl/g and more preferably 0.06 to 0.095 dl/g. When this intrinsic viscosity is too low, the molecular weight tends to be low, and low dielectric properties such as a low relative dielectric constant and a low dielectric loss tangent tend to be hardly attained. When the intrinsic viscosity is too high, the viscosity is high, sufficient fluidity is not attained, and the moldability of the cured product tends to decrease. Thus, when the intrinsic viscosity of the polyphenylene ether compound is in the above range, excellent heat resistance and moldability of the cured product can be realized.

The intrinsic viscosity here is an intrinsic viscosity measured in methylene chloride at 25° C. and more specifically is, for example, a value attained by measuring the intrinsic viscosity of a methylene chloride solution (liquid temperature: 25° C.) at 0.18 g/45 ml using a viscometer. Examples of the viscometer include AVS500 Visco System manufactured by SCHOTT Instruments GmbH.

Examples of the polyphenylene ether compound (A1) include a polyphenylene ether compound represented by the following Formula (7) and a polyphenylene ether compound represented by the following Formula (8). As the polyphenylene ether compound (A1), these polyphenylene ether compounds may be used singly or these two polyphenylene ether compounds may be used in combination.

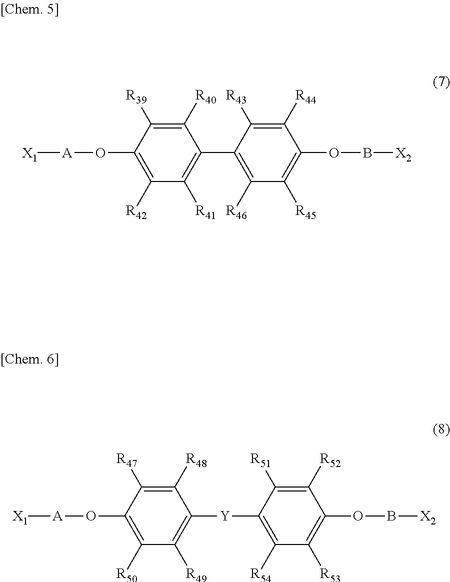

In Formulas (7) and (8), R₃₉ to R₄₆ and R₄₇ to R₅₄ are independent of each other. In other words, R₃₉ to R₄₆ and R₄₇ to R₅₄ may be the same group as or different groups from each other. R₃₉ to R₄₆ and R₄₇ to R₅₄ represent a hydrogen atom, an alkyl group, an alkenyl group, an alkynyl group, a formyl group, an alkylcarbonyl group, an alkenylcarbonyl group, or an alkynylcarbonyl group. X₁ and X₂ are independent of each other. In other words, X₁ and X₂ may be the same group as or different groups from each other. X₁ and X₂ represent a substituent having a carbon-carbon unsaturated double bond. A and B represent a repeating unit represented by the following Formula (9) and a repeating unit represented by the following Formula (10), respectively. In Formula (8), Y represents a linear, branched, or cyclic hydrocarbon having 20 or less carbon atoms.

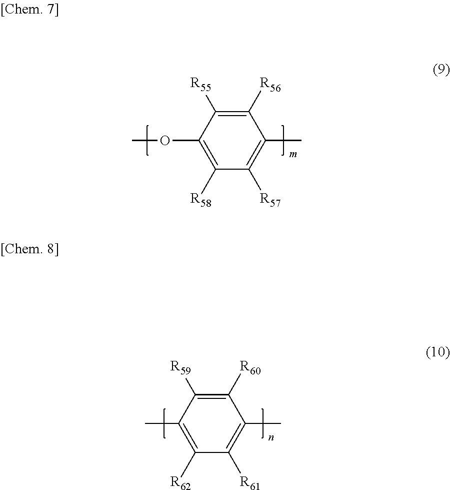

In Formulas (9) and (10), m and n each represent 0 to 20. R₅₈ to R₅₈ and R₅₉ to R₆₂ are independent of each other. That is, R₅₅ to R₅₈ and R₅₉ to R₆₂ may be the same group as or different groups from each other. R₅₅ to R₅₈ and R₅₉ to R₆₂ represent a hydrogen atom, an alkyl group, an alkenyl group, an alkynyl group, a formyl group, an alkylcarbonyl group, an alkenylcarbonyl group, or an alkynylcarbonyl group.

The polyphenylene ether compound represented by Formula (7) and the polyphenylene ether compound represented by Formula (8) are not particularly limited as long as they are compounds satisfying the configuration. Specifically, in Formulas (7) and (8), R₃₉ to R₄₆ and R₄₇ to R₅₄ are independent of each other as described above. In other words, R₃₉ to R₄₆ and R₄₇ to R₅₄ may be the same group as or different groups from each other. R₃₉ to R₄₆ and R₄₇ to R₅₄ represent a hydrogen atom, an alkyl group, an alkenyl group, an alkynyl group, a formyl group, an alkylcarbonyl group, an alkenylcarbonyl group, or an alkynylcarbonyl group. Among them, each of R₃₉ to RAG and R₄₇ to R₅₄ is preferably a hydrogen atom and an alkyl group.

In Formulas (9) and (10), m and n each preferably represent 0 to 20 as described above. In addition, it is preferable that m and n represent numerical values so that the sum of m and n is 1 to 30. Hence, it is more preferable that m represents 0 to 20, n represents 0 to 20, and the sum of m and n represents 1 to 30. R₅₅ to R₅₈ and R₅₉ to R₆₂ are independent of each other. That is, R₅₅ to R₅₈ and R₅₉ to R₆₂ may be the same group as or different groups from each other. R₅₅ to R₅₈ and R₅₉ to R₆₂ represent a hydrogen atom, an alkyl group, an alkenyl group, an alkynyl group, a formyl group, an alkylcarbonyl group, an alkenylcarbonyl group, or an alkynylcarbonyl group. Among them, each of R₅₅ to R₅₈ and R₅₉ to R₆₂ is preferably a hydrogen atom and an alkyl group. R₃₉ to R₆₂ are the same as R₃₅ to R₃₈ in Formula (6).

In Formula (8), Y represents a linear, branched, or cyclic hydrocarbon having 20 or less carbon atoms as described above. Examples of Y include a group represented by the following Formula (11).

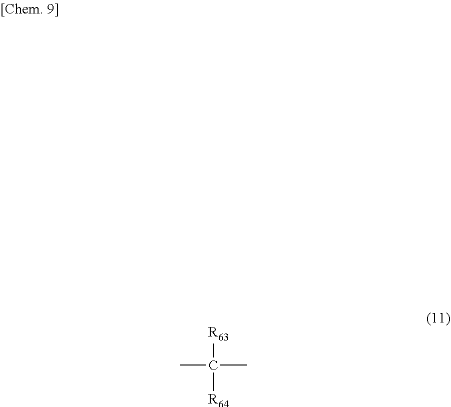

In Formula (11), R₆₃ and R₆₄ each independently represent a hydrogen atom or an alkyl group. Examples of the alkyl group include a methyl group. Examples of the group represented by Formula (11) include a methylene group, a methylmethylene group, and a dimethylmethylene group. Among them, a dimethylmethylene group is preferable.

In Formulas (7) and (8), X₁ and X₂ each independently represent a substituent having a carbon-carbon double bond. In the polyphenylene ether compound represented by Formula (7) and the polyphenylene ether compound represented by Formula (8), X₁ and X₂ may be the same group as or different groups from each other.

More specific examples of the polyphenylene ether compound represented by Formula (7) include a polyphenylene ether compound represented by the following Formula (12).

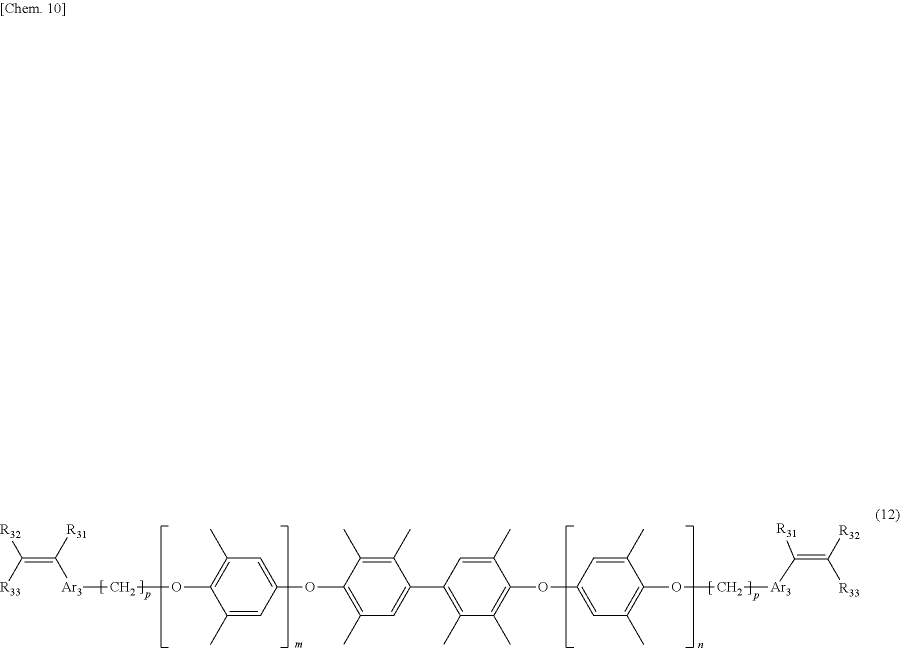

More specific examples of the polyphenylene ether compound represented by Formula (8) include a polyphenylene ether compound represented by the following Formula (13) and a polyphenylene ether compound represented by the following Formula (14).

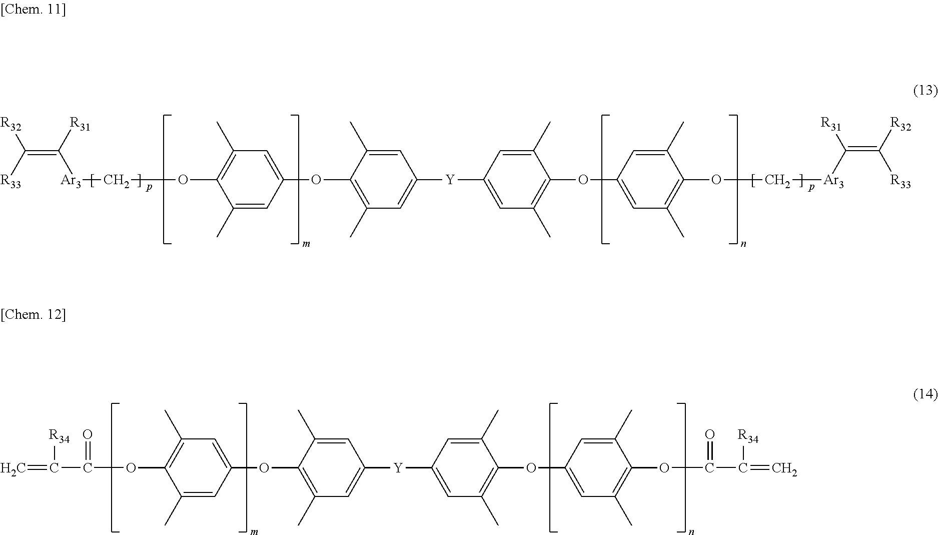

In Formulas (12) to (14), m and n are the same as m and n in Formulas (9) and (10). In Formulas (12) and (13), R₃₁ to R₃₃, p, and Ar₃ are the same as R₃₁ to R₃₃, p, and Ar₃ in Formula (3). In Formulas (13) and (14), Y is the same as Y in Formula (8). In Formula (14), R₃₄ is the same as R₃₄ in Formula (4).

The method for synthesizing the polyphenylene ether compound (A1) used in the present embodiment is not particularly limited as long as a polyphenylene ether compound having a carbon-carbon unsaturated double bond in the molecule can be synthesized. Specific examples of this method include a method in which polyphenylene ether is reacted with a compound in which a substituent having a carbon-carbon unsaturated double bond is bonded to a halogen atom.

Examples of the compound in which a substituent having a carbon-carbon unsaturated double bond is bonded to a halogen atom include compounds in which substituents represented by Formulas (3) to (5) are bonded to a halogen atom. Specific examples of the halogen atom include a chlorine atom, a bromine atom, an iodine atom, and a fluorine atom. Among them, a chlorine atom is preferable. More specific examples of the compound in which a substituent having a carbon-carbon unsaturated double bond is bonded to a halogen atom include o-chloromethylstyrene, p-chloromethylstyrene, and m-chloromethylstyrene. The compound in which a substituent having a carbon-carbon unsaturated double bond is bonded to a halogen atom may be used singly or in combination of two or more kinds thereof. For example, o-chloromethylstyrene, p-chloromethylstyrene, and m-chloromethylstyrene may be used singly or in combination of two or three kinds thereof.

Polyphenylene ether that is a raw material is not particularly limited as long as a predetermined polyphenylene ether compound can be finally synthesized. Specific examples thereof include those containing polyphenylene ether containing 2,6-dimethylphenol and at least one of a bifunctional phenol and a trifunctional phenol and polyphenylene ether such as poly(2,6-dimethyl-1,4-phenylene oxide) as a main component. The bifunctional phenol is a phenol compound having two phenolic hydroxyl groups in the molecule, and examples thereof include tetramethyl bisphenol A. The trifunctional phenol is a phenol compound having three phenolic hydroxyl groups in the molecule.

Examples of the method for synthesizing the polyphenylene ether compound (A1) include the methods described above. Specifically, polyphenylene ether as described above and the compound in which a substituent having a carbon-carbon unsaturated double bond is bonded to a halogen atom are dissolved in a solvent and stirred. By doing so, polyphenylene ether reacts with the compound in which a substituent having a carbon-carbon unsaturated double bond is bonded to a halogen atom, and the polyphenylene ether compound used in the present embodiment is obtained.

In the reaction, it is preferable to carry out the reaction in the presence of an alkali metal hydroxide. By doing so, it is considered that this reaction suitably proceeds. This is considered to be because the alkali metal hydroxide functions as a dehydrohalogenating agent, specifically, a dehydrochlorinating agent. In other words, it is considered that the alkali metal hydroxide eliminates the hydrogen halide from the phenol group in polyphenylene ether and the compound in which a substituent having a carbon-carbon unsaturated double bond is bonded to a halogen atom, and by doing so, the substituent having a carbon-carbon unsaturated double bond is bonded to the oxygen atom of the phenol group instead of the hydrogen atom of the phenol group in polyphenylene ether.

The alkali metal hydroxide is not particularly limited as long as it can act as a dehalogenating agent, and examples thereof include sodium hydroxide. The alkali metal hydroxide is usually used in the form of an aqueous solution, specifically, in the form of an aqueous solution of sodium hydroxide.

The reaction conditions such as reaction time and reaction temperature also vary depending on the compound in which a substituent having a carbon-carbon unsaturated double bond is bonded to a halogen atom, and the like, and are not particularly limited as long as they are conditions under which the reaction as described above suitably proceeds. Specifically, the reaction temperature is preferably room temperature to 100° C., and more preferably 30° C. to 100° ° C. The reaction time is preferably 0.5 to 20 hours, more preferably 0.5 to 10 hours.

The solvent used at the time of the reaction is not particularly limited as long as it can dissolve polyphenylene ether and the compound in which a substituent having a carbon-carbon unsaturated double bond is bonded to a halogen atom, and does not inhibit the reaction of polyphenylene ether with the compound in which a substituent having a carbon-carbon unsaturated double bond is bonded to a halogen atom. Specific examples of the solvent include toluene.

The reaction described above is preferably performed in the presence of not only an alkali metal hydroxide but also a phase-transfer catalyst. In other words, the above reaction is preferably conducted in the presence of an alkali metal hydroxide and a phase transfer catalyst. By doing so, it is considered that the above reaction more suitably proceeds. This is considered to be due to the following. This is considered to be because the phase transfer catalyst is a catalyst which has a function of taking in the alkali metal hydroxide, is soluble in both phases of a phase of a polar solvent such as water and a phase of a non-polar solvent such as an organic solvent, and can transfer between these phases. Specifically, in a case where an aqueous sodium hydroxide solution is used as an alkali metal hydroxide and an organic solvent, such as toluene, which is not compatible with water is used as a solvent, it is considered that when the aqueous sodium hydroxide solution is dropped into the solvent subjected to the reaction as well, the solvent and the aqueous sodium hydroxide solution are separated from each other and the sodium hydroxide is hardly transferred to the solvent. In that case, it is considered that the aqueous sodium hydroxide solution added as an alkali metal hydroxide hardly contributes to the promotion of the reaction. In contrast, when the reaction is conducted in the presence of an alkali metal hydroxide and a phase transfer catalyst, it is considered that the alkali metal hydroxide is transferred to the solvent in the state of being taken in the phase transfer catalyst and the aqueous sodium hydroxide solution is likely to contribute to the promotion of the reaction. For this reason, this is considered that the reaction proceeds favorably in the presence of the alkali metal hydroxide and the phase-transfer catalyst.

The phase transfer catalyst is not particularly limited, and examples thereof include quaternary ammonium salts such as tetra-n-butylammonium bromide.

The resin composition used in the present embodiment preferably contains a polyphenylene ether compound obtained as described above as the polyphenylene ether compound.

Examples of the radical-polymerizable compound (other radical-polymerizable compound) (A2) other than the polyphenylene ether compound include a vinyl compound, an allyl compound, a methacrylate compound, an acrylate compound, and an acenaphthylene compound.

The vinyl compound is a compound having a vinyl group in the molecule. Examples of the vinyl compound include a monofunctional vinyl compound (monovinyl compound) having one vinyl group in the molecule and a polyfunctional vinyl compound having two or more vinyl groups in the molecule. Examples of the monofunctional vinyl compound include a styrene compound. Examples of the polyfunctional vinyl compound include a polyfunctional aromatic vinyl compound and a vinyl hydrocarbon-based compound. Examples of the polyfunctional aromatic vinyl compound include divinylbenzene. Examples of the vinyl hydrocarbon-based compound include a polybutadiene compound.

The allyl compound is a compound having an allyl group in the molecule, and examples thereof include a triallyl isocyanurate compound such as triallyl isocyanurate (TAIC), a diallyl bisphenol compound, and diallyl phthalate (DAP).

The methacrylate compound is a compound having a methacryloyl group in the molecule, and examples thereof include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include dimethacrylate compounds such as tricyclodecanedimethanol dimethacrylate (DCP).

The acrylate compound is a compound having an acryloyl group in the molecule, and examples thereof include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include diacrylate compounds such as tricyclodecanedimethanol diacrylate.

The acenaphthylene compound is a compound having an acenaphthylene structure in the molecule. Examples of the acenaphthylene compound include acenaphthylene, alkylacenaphthylenes, halogenated acenaphthylenes, and phenylacenaphthylenes. Examples of the alkylacenaphthylenes include 1-methyl acenaphthylene, 3-methyl acenaphthylene, 4-methyl acenaphthylene, 5-methyl acenaphthylene, 1-ethyl acenaphthylene, 3-ethyl acenaphthylene, 4-ethyl acenaphthylene, and 5-ethyl acenaphthylene. Examples of the halogenated acenaphthylenes include 1-chloroacenaphthylene, 3-chloroacenaphthylene, 4-chloroacenaphthylene, 5-chloroacenaphthylene, 1-bromoacenaphthylene, 3-bromoacenaphthylene, 4-bromoacenaphthylene, and 5-bromoacenaphthylene. Examples of the phenylacenaphthylenes include 1-phenylacenaphthylene, 3-phenylacenaphthylene, 4-phenylacenaphthylene, and 5-phenylacenaphthylene. The acenaphthylene compound may be a monofunctional acenaphthylene compound having one acenaphthylene structure in the molecule as described above or may be a polyfunctional acenaphthylene compound having two or more acenaphthylene structures in the molecule.

The radical-polymerizable compound (A) may be formed of the polyphenylene ether compound (A1), or may be formed of the radical-polymerizable compound (other radical-polymerizable compound) (A2) other than the polyphenylene ether compound (A1). As described above, the radical-polymerizable compound (A) preferably contains the polyphenylene ether compound (A1), and more preferably contains the polyphenylene ether compound (A1) and the other radical-polymerizable compound (A2). The other radical-polymerizable compound may be used singly or in combination of two or more kinds thereof. As the other radical-polymerizable compound, among the radical-polymerizable compounds described above, a polyfunctional aromatic vinyl compound, an allyl compound, a polyfunctional methacrylate compound, a polyfunctional acrylate compound, a polybutadiene compound, an acenaphthylene compound, a styrene compound, and the like are preferable.

The weight average molecular weight of the radical-polymerizable compound (A) varies depending on the radical-polymerizable compound (A), is not particularly limited, and is, for example, preferably less than 10,000, and more preferably 500 to 5,000. When the radical-polymerizable compound (A) is, for example, the polyphenylene ether compound (A1), as described above, the weight average molecular weight thereof is preferably 500 to 5,000, more preferably 800 to 4,000, still more preferably 1,000 to 3,000. Here, the weight average molecular weight may be measured by a general molecular weight measurement method, and the weight average molecular weight is specifically a value measured by gel permeation chromatography (GPC) or the like.

When the radical-polymerizable compound (A) contains the polyphenylene ether compound (A1), the content of the polyphenylene ether compound (A1) is preferably 30 to 100 parts by mass, and more preferably 50 to 80 parts by mass, with respect to 100 parts by mass of the radical-polymerizable compound (A). When the content of the polyphenylene ether compound (A1) is in the above range, the resin composition can be suitably cured, and in the cured product, the glass transition temperature can be sufficiently increased while maintaining excellent low dielectric properties, interlayer adhesion, and flame retardancy.

### (Phosphoric Acid Ester Compound (B))

The phosphoric acid ester compound (B) is not particularly limited as long as it is a phosphoric acid ester compound having an alicyclic hydrocarbon structure in the molecule. The alicyclic hydrocarbon structure is not particularly limited and is, for example, preferably a 3 to 12 membered saturated alicyclic hydrocarbon structure, and more preferably a 5 to 7 membered saturated alicyclic hydrocarbon structure. That is, the phosphoric acid ester compound (B) preferably contains the 3 to 12 membered saturated alicyclic hydrocarbon structure as the alicyclic hydrocarbon structure, and more preferably contains the 5 to 7 membered saturated alicyclic hydrocarbon structure. Examples of the alicyclic hydrocarbon structure include a divalent group of a saturated alicyclic hydrocarbon, and the alicyclic hydrocarbon structure may have a substituent bonded to carbon constituting a ring. The alicyclic hydrocarbon structure may be a monocyclic alicyclic hydrocarbon structure or a polycyclic alicyclic hydrocarbon structure. Examples of the alicyclic hydrocarbon structure include divalent groups of cycloalkanes such as cyclopropane, cyclobutane, cyclopentane, cyclohexane, cycloheptane, cyclooctane, cyclononane, cyclodecane, cycloundecane, and cyclododecane. Examples of the polycyclic alicyclic hydrocarbon structure include a divalent group of bicyclic alicyclic hydrocarbon and a divalent group of tricyclic alicyclic hydrocarbon. Examples of the divalent group of the bicyclic alicyclic hydrocarbon include divalent groups of bicyclic alicyclic hydrocarbon such as bicyclo [1.1.0] butane, bicyclo [3.2.1] octane, bicyclo [5.2.0] nonane, and bicyclo [4.3.2] undecane. Examples of the divalent group of the tricyclic alicyclic hydrocarbon include divalent groups of tricyclic alicyclic hydrocarbon such as tricyclo[2.2.1.0] heptane and tricyclo [5.3.1.1] dodecane. The alicyclic hydrocarbon structure may be used singly or in combination of two or more thereof. The substituent bonded to the carbon constituting the ring is not particularly limited, examples thereof include an alkyl group, an alkenyl group, an alkynyl group, a formyl group, an alkylcarbonyl group, an alkenylcarbonyl group, and an alkynylcarbonyl group, and more specific examples thereof include substituents exemplified as R₁ to R₁₀ described later. These substituents may be used singly or in combination of two or more thereof. That is, the number of substituents bonded to the carbon constituting the ring of the alicyclic hydrocarbon structure may be one, or two or more, and in the case of two or more, the substituents may be the same group as or different groups from each other. When the number of the substituents is two or more, the substituents may be bonded to the same carbon among the carbons constituting the ring of the alicyclic hydrocarbon structure, or may be bonded to different carbons.

Among the carbons constituting the ring of the alicyclic hydrocarbon structure, two bonds may be formed on the same carbon as in a divalent group represented by the following Formulas (15) to (18), or may be formed on different carbons.

More specific examples of the alicyclic hydrocarbon structure include divalent groups represented by the following Formulas (15) to (18).

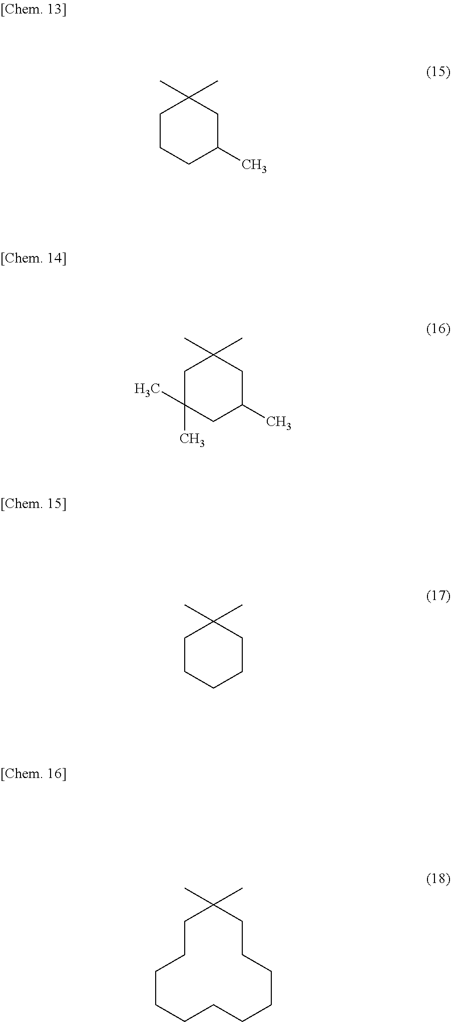

Examples of the phosphoric acid ester compound (B) include a phosphoric acid ester compound having at least one structure represented by the following Formula (1) in the molecule. That is, examples of the phosphoric acid ester compound (B) include a phosphoric acid ester compound having a structure represented by the following Formula (1) as a phosphorus-containing structure in the phosphoric acid ester compound (B). More specific examples of the phosphoric acid ester compound (B) include a phosphoric acid ester compound having the alicyclic hydrocarbon structure and the structure represented by the following Formula (1) in the molecule.

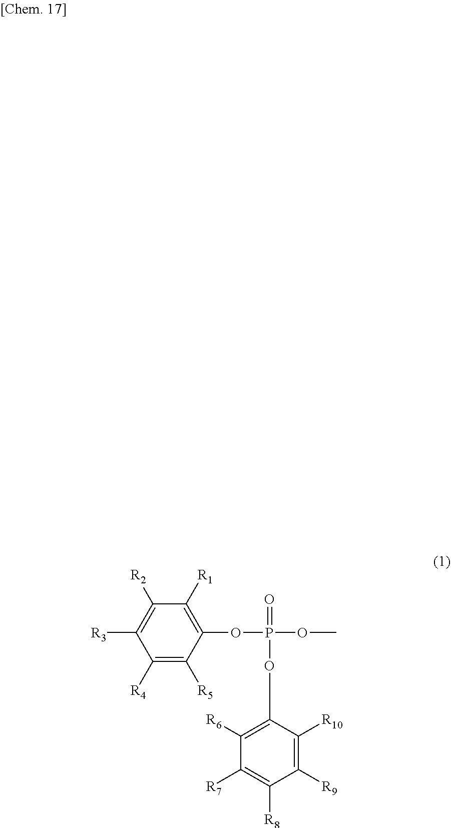

In Formula (1), R₁ to R₁₀ are independent of each other. That is, R₁ to R₁₀ may be the same group as or different groups from each other. R₁ to R₁₀ represent a hydrogen atom, an alkyl group, an alkenyl group, an alkynyl group, a formyl group, an alkylcarbonyl group, an alkenylcarbonyl group, or an alkynylcarbonyl group.

The structure represented by Formula (1) is not particularly limited, and preferably has a substituent at an ortho position. Specifically, in the structure represented by Formula (1), R₁, R₅, R₆, and R₁₀ are each other than a hydrogen atom, that is, an alkyl group, an alkenyl group, an alkynyl group, a formyl group, an alkylcarbonyl group, an alkenylcarbonyl group, or an alkynylcarbonyl group, and in the structure represented by Formula (1), groups other than R₁, R₅, R₆, and R₁₀ (that is, R₂ to R₄ and Ry to R₉) are preferably hydrogen atoms. Specific examples of R₁ to R₁₀ in Formula (1) include the following groups.

The alkyl group is not particularly limited, and is preferably an alkyl group having 1 to 10 carbon atoms, more preferably an alkyl group having 1 to 6 carbon atoms, and still more preferably an alkyl group having 1 to 4 carbon atoms. R₁, R₅, R₆, and R₁₀ are particularly preferably alkyl groups having 1 to 4 carbon atoms. The alkyl group may be linear or branched.

Examples of the alkyl group include a methyl group, an ethyl group, an n-propyl group, an isopropyl group, an n-butyl group, an isobutyl group, a tert-butyl group, an n-pentyl group, an isopentyl group, a 2-methylbutyl group, a 1-methylbutyl group, a 1,2-dimethylpropyl group, a neopentyl group (2,2-dimethylpropyl group), a tert-pentyl group (1,1-dimethylpropyl group), an n-hexyl group, an isohexyl group, a 1-methylpentyl group, a 2-methylpentyl group, a 3-methylpentyl group, a 1-ethylbutyl group, a 2-ethylbutyl group, a 1,1-dimethylbutyl group, a 1,2-dimethylbutyl group, a 1,3-dimethylbutyl group, a 2,2-dimethylbutyl group, a 2,3-dimethylbutyl group, a 1-ethyl-1-methylpropyl group, a 1-ethyl-2-methylpropyl group, an n-heptyl group, an isoheptyl group, a 1-methylhexyl group, a 2-methylhexyl group, a 3-methylhexyl group, a 4-methylhexyl group, a 1-ethylpentyl group, a 2-ethylpentyl group, a 3-ethylpentyl group, a 1-propylbutyl group, a 1,1-dimethylpentyl group, a 1,2-dimethylpentyl group, a 1,3-dimethylpentyl group, a 1,4-dimethylpentyl group, a 1-ethyl-1-methylbutyl group, a 1-ethyl-2-methylbutyl group, a 1-ethyl-3-methylbutyl group, a 2-ethyl-1-methylbutyl group, a 2-ethyl-1-methylbutyl group, a 2-ethyl-2-methylbutyl group, a 2-ethyl-3-methylbutyl group, a 1,1-diethylpropyl group, an n-octyl group, an isooctyl group, a 1-methylheptyl group, a 2-methylheptyl group, a 3-methylheptyl group, a 4-methylheptyl group, a 5-methylheptyl group, a 1-ethylhexyl group, a 2-ethylhexyl group, a 3-ethylhexyl group, a 4-ethylhexyl group, a 1-propylheptyl group, a 2-propylheptyl group, a nonyl group, and a decyl group. Among them, more preferred are alkyl groups having 1 to 6 carbon atoms such as a methyl group, an ethyl group, an n-propyl group, an isopropyl group, an n-butyl group, an isobutyl group, a tert-butyl group, an n-pentyl group, an isopentyl group, a 2-methylbutyl group, a 1-methylbutyl group, a 1,2-dimethylpropyl group, a neopentyl group (2,2-dimethylpropyl group), a tert-pentyl group (1,1-dimethylpropyl group), an n-hexyl group, an isohexyl group, a 1-methylpentyl group, a 2-methylpentyl group, a 3-methylpentyl group, a 1-ethylbutyl group, a 2-ethylbutyl group, a 1,1-dimethylbutyl group, a 1,2-dimethylbutyl group, a 1,3-dimethylbutyl group, a 2,2-dimethylbutyl group, a 2,3-dimethylbutyl group, a 1-ethyl-1-methylpropyl group, and a 1-ethyl-2-methylpropyl group, and still more preferred are alkyl groups having 1 to 4 carbon atoms such as a methyl group, an ethyl group, a n-propyl group, an isopropyl group, an n-butyl group, an isobutyl group, and a tert-butyl group.

The alkenyl group is not particularly limited, and is preferably an alkenyl group having 1 to 10 carbon atoms, more preferably an alkonyl group having 1 to 6 carbon atoms, and still more preferably an alkenyl group having 1 to 4 carbon atoms. R₁, R₅, R₆, and R₁₀ are particularly preferably alkenyl groups having 1 to 4 carbon atoms. The alkenyl group may be linear or branched.

Examples of the alkenyl group include a methoxy group, an ethoxy group, an n-propoxy group, an isopropoxy group, an n-butoxy group, an isobutoxy group, a tert-butoxy group, an n-pentyloxy group, an isopentyloxy group, a 2-methylbutoxy group, a 1-methylbutoxy group, a 1,2-dimethylpropoxy group, a neopentyloxy group (2,2-dimethylpropoxy group), a tert-pentyloxy group (1,1-dimethylpropoxy group), an n-hexyloxy group, an isohexyloxy group, a 1-methylpentyloxy group, a 2-methylpentyloxy group, a 3-methylpentyloxy group, a 1-ethylbutoxy group, a 2-ethylbutoxy group, a 1,1-dimethylbutoxy group, a 1,2-dimethylbutoxy group, a 1,3-dimethylbutoxy group, a 2,2-dimethylbutoxy group, a 2,3-dimethylbutoxy group, a 1-ethyl-1-methylpropoxy group, a 1-ethyl-2-methylpropoxy group, an n-heptyloxy group, an isoheptyloxy group, a 1-methylhexyloxy group, a 2-methylhexyloxy group, a 3-methylhexyloxy group, a 4-methylhexyloxy group, a 1-ethylpentyloxy group, a 2-ethylpentyloxy group, a 3-ethylpentyloxy group, a 1-propylbutoxy group, a 1,1-dimethylpentyloxy group, a 1,2-dimethylpentyloxy group, a 1,3-dimethylpentyloxy group, a 1,4-dimethylpentyloxy group, a 1-ethyl-1-methylbutoxy group, a 1-ethyl-2-methylbutoxy group, a 1-ethyl-3-methylbutoxy group, a 2-ethyl-1-methylbutoxy group, a 2-ethyl-1-methylbutoxy group, a 2-ethyl-2-methylbutoxy group, a 2-ethyl-3-methylbutoxy group, a 1,1-diethylpropoxy group, an n-octyloxy group, an isooctyloxy group, a 1-methylheptyloxy group, a 2-methylheptyloxy group, a 3-methylheptyloxy group, a 4-methylheptyloxy group, a 5-methylheptyloxy group, a 1-ethylhexyloxy group, a 2-ethylhexyloxy group, a 3-ethylhexyloxy group, a 4-ethylhexyloxy group, a 1-propylheptyloxy group, a 2-propylheptyloxy group, a nonyloxy group, and a decyloxy group. Among them, more preferred are alkenyl groups having 1 to 6 carbon atoms such as a methoxy group, an ethoxy group, an n-propoxy group, an isopropoxy group, an n-butoxy group, an isobutoxy group, a tert-butoxy group, an n-pentyloxy group, an isopentyloxy group, a 2-methylbutoxy group, a 1-methylbutoxy group, a 1,2-dimethylpropoxy group, a neopentyloxy group (2,2-dimethylpropoxy group), a tert-pentyloxy group (1,1-dimethylpropoxy group), an n-hexyloxy group, an isohexyloxy group, a 1-methylpentyloxy group, a 2-methylpentyloxy group, a 3-methylpentyloxy group, a 1-ethylbutoxy group, a 2-ethylbutoxy group, a 1,1-dimethylbutoxy group, a 1,2-dimethylbutoxy group, a 1,3-dimethylbutoxy group, a 2,2-dimethylbutoxy group, a 2,3-dimethylbutoxy group, a 1-ethyl-1-methylpropoxy group, and a 1-ethyl-2-methylpropoxy group, and still more preferred are alkenyl groups having 1 to 4 carbon atoms such as a methoxy group, an ethoxy group, an n-propoxy group, an isopropoxy group, an n-butoxy group, an isobutoxy group, and a tert-butoxy group.

The alkynyl group is not particularly limited and is, for example, preferably an alkynyl group having 2 to 18 carbon atoms, more preferably an alkynyl group having 2 to 10 carbon atoms. Specific examples of the alkynyl group include an ethynyl group, and a prop-2-yn-1-yl group (propargyl group).

The alkylcarbonyl group is not particularly limited as long as it is a carbonyl group substituted with an alkyl group and is, for example, preferably an alkylcarbonyl group having 2 to 18 carbon atoms, more preferably an alkylcarbonyl group having 2 to 10 carbon atoms. Specific examples of the alkylcarbonyl group include an acetyl group, a propionyl group, a butyryl group, an isobutyryl group, a pivaloyl group, a hexanoyl group, an octanoyl group, and a cyclohexylcarbonyl group.

The alkenylcarbonyl group is not particularly limited as long as it is a carbonyl group substituted with an alkenyl group and is, for example, preferably an alkenylcarbonyl group having 3 to 18 carbon atoms, more preferably an alkenylcarbonyl group having 3 to 10 carbon atoms. Specific examples of the alkenylcarbonyl group include an acryloyl group, a methacryloyl group, and a crotonoyl group.

The alkynylcarbonyl group is not particularly limited as long as it is a carbonyl group substituted with an alkynyl group and is, for example, preferably an alkynylcarbonyl group having 3 to 18 carbon atoms, more preferably an alkynylcarbonyl group having 3 to 10 carbon atoms. Specific examples of the alkynylcarbonyl group include a propioloyl group.

The structure represented by Formula (1) may have any one of a hydrogen atom, the alkyl group, the alkenyl group, the alkynyl group, the formyl group, the alkylcarbonyl group, the alkenylcarbonyl group, and the alkynylcarbonyl group, or may have a combination of two or more thereof.

Specific examples of the phosphoric acid ester compound (B) include a phosphoric acid ester compound represented by the following Formula (2), and it is preferable to include this phosphoric acid ester compound.

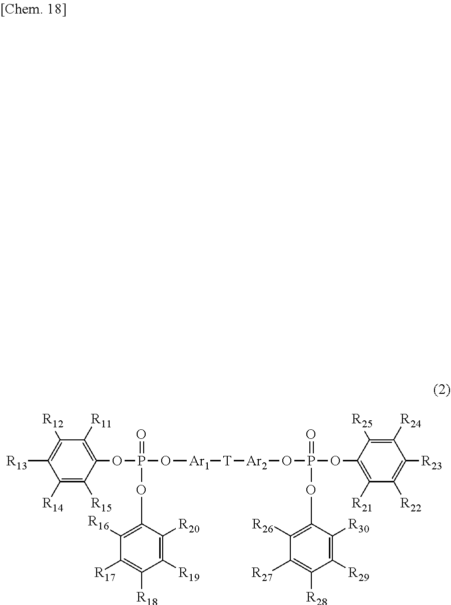

In Formula (2), R₁₁ to R₃₀ are independent of each other. That is, Ru to R₃₀ may be the same group as or different groups from each other. R₁₁ to R₃₀ represent a hydrogen atom, an alkyl group, an alkenyl group, an alkynyl group, a formyl group, an alkylcarbonyl group, an alkenylcarbonyl group, or an alkynylcarbonyl group. Ar₁ and Ar₂ each independently represent an arylene group. T represents a divalent group of a 3 to 12 membered saturated alicyclic hydrocarbon.

The groups of Ru to R₃₀ in Formula (2) include groups similar to R₁ to R₁₀ in Formula (1).

The arylene group is not particularly limited. Examples of the arylene group include a monocyclic aromatic group such as a phenylene group and a polycyclic aromatic group that is polycyclic aromatic such as a naphthalene ring. Examples of the arylene group include a group represented by the following Formula (19).

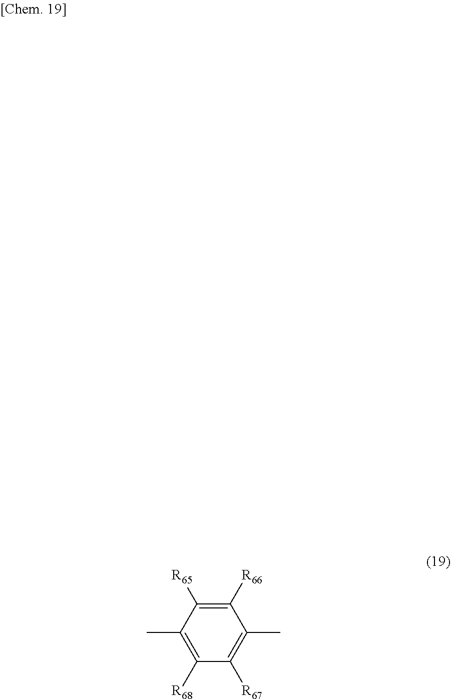

In Formula (19), Res to R₆₈ are independent of each other. That is, R₆₅ to R₆₈ may be the same group as or different groups from each other. R₆₅ to R₆₈ represent a hydrogen atom, an alkyl group, an alkenyl group, an alkynyl group, a formyl group, an alkylcarbonyl group, an alkenylcarbonyl group, or an alkynylcarbonyl group.

The groups of Res to Res in Formula (19) include groups similar to R₁ to R₁₀ in Formula (1).

Specific examples of the phosphoric acid ester compound (B) include compounds represented by the following Formulae (20) to (23).

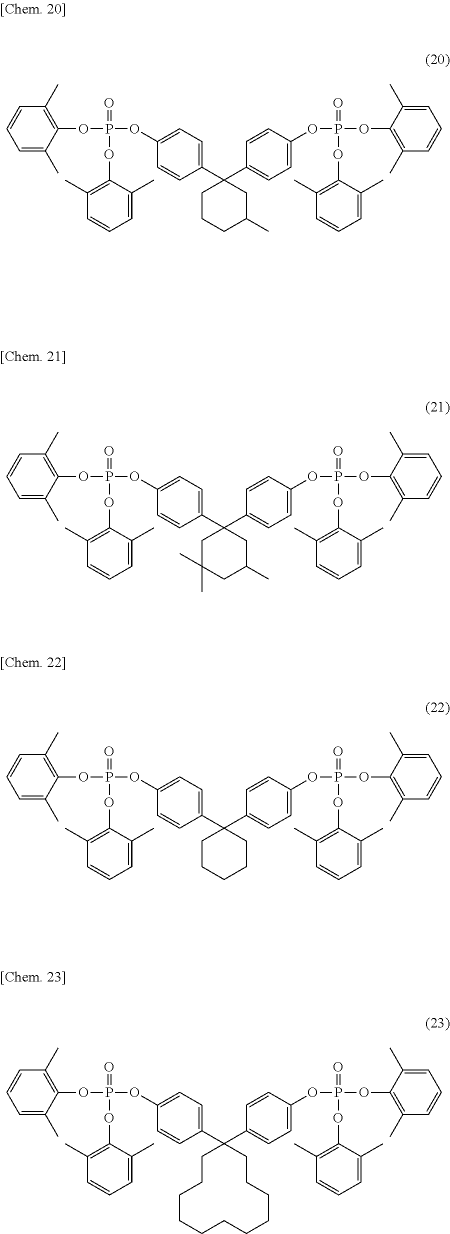 [SMILES: Cc1cccc(C)c1OP(=O)(Oc1ccc(C2(c3ccc(OP(=O)(Oc4c(C)cccc4C)Oc4c(C)cccc4C)cc3)CCCC(C)C2)cc1)Oc1c(C)cccc1C ; Cc1cccc(C)c1OP(=O)(Oc1ccc(C2(c3ccc(OP(=O)(Oc4c(C)cccc4C)Oc4c(C)cccc4C)cc3)CC(C)CC(C)(C)C2)cc1)Oc1c(C)cccc1C ; Cc1cccc(C)c1OP(=O)(Oc1ccc(C2(c3ccc(OP(=O)(Oc4c(C)cccc4C)Oc4c(C)cccc4C)cc3)CCCCC2)cc1)Oc1c(C)cccc1C ; Cc1cccc(C)c1OP(=O)(Oc1ccc(C2(c3ccc(OP(=O)(Oc4c(C)cccc4C)Oc4c(C)cccc4C)cc3)CCCCCCCCCCC2)cc1)Oc1c(C)cccc1C]

The phosphoric acid ester compound (B) may be used singly or in combination of two or more kinds thereof.

A method of producing the phosphoric acid ester compound (B) is not particularly limited as long as the phosphoric acid ester compound (B) can be produced, and a known method can be used. Examples of the method of producing the phosphoric acid ester compound (B) include a method using phosphoryl chloride (phosphorus oxychloride).

### (Content)

The content of the phosphoric acid ester compound (B) is preferably 5 to 60 parts by mass, more preferably 10 to 50 parts by mass, and still more preferably 15 to 45 parts by mass, with respect to 100 parts by mass of the radical-polymerizable compound (A). When the content of the phosphoric acid ester compound (B) is too small, the flame retardancy of the obtained cured product tends to be insufficient. When the content of the phosphoric acid ester compound (B) is too large, the content of the radical-polymerizable compound (A) is relatively too small, so that the glass transition temperature of the obtained cured product tends to be lowered or the interlayer adhesion tends to be insufficient. From these facts, when the content of the phosphoric acid ester compound (B) is in the above range, a resin composition capable of exhibiting sufficient flame retardancy while suppressing the decrease in the glass transition temperature and interlayer adhesion in the cured product is obtained.

### (Styrenic Copolymer)

The resin composition may contain a styrenic copolymer. It is considered that inclusion of the styrenic copolymer in the resin composition has advantages that the dielectric constant of the obtained cured product can be further reduced, and handleability (film properties) is improved when a resin composition or a semi-cured product (B stage) of the resin composition is prepared.

The styrenic copolymer is not particularly limited and is, for example, a copolymer obtained by polymerizing a monomer including a styrenic monomer. Examples of the styrenic copolymer include a copolymer obtained by copolymerizing one or more styrenic monomers and one or more other monomers copolymerizable with the styrenic monomers. The styrenic copolymer may be a random copolymer, a block copolymer, an alternating copolymer, or a graft copolymer as long as it has a structure derived from the styrenic monomer in the molecule. Among them, the styrenic copolymer is preferably a block copolymer, that is, a styrenic block copolymer. The styrenic block copolymer is not particularly limited and is, for example, a block copolymer obtained by polymerizing a monomer including a styrenic monomer. That is, the styrenic block copolymer is a block copolymer having at least a structure (repeating unit) derived from the styrenic monomer in the molecule. Examples of the styrenic block copolymer include a block copolymer obtained by copolymerizing one or more styrenic monomers and one or more other monomers copolymerizable with the styrenic monomers. As described above, the styrenic block copolymer may be the block copolymer having at least the structure (repeating unit) derived from the styrenic monomer in the molecule, and examples thereof include a binary copolymer, a ternary copolymer, and a quaternary or higher copolymer. The binary copolymer is a binary copolymer of the structure (repeating unit) derived from the styrenic monomer and a structure (repeating unit) derived from the other copolymerizable monomer. Examples of the ternary copolymer include a ternary copolymer of the structure (repeating unit) derived from the styrenic monomer, the structure (repeating unit) derived from the other copolymerizable monomer, and the structure (repeating unit) derived from the styrenic monomer, and a ternary copolymer of the structure (repeating unit) derived from the other copolymerizable monomer, the structure (repeating unit) derived from the styrenic monomer, and the structure (repeating unit) derived from the other copolymerizable monomer. The styrenic copolymer may be a hydrogenated styrenic copolymer obtained by hydrogenating the styrenic copolymer. The styrenic copolymer may be a hydrogenated styrenic block copolymer obtained by hydrogenating the styrenic block copolymer.

The styrenic monomer is not particularly limited, and examples thereof include styrene, a styrene derivative, one in which some hydrogen atoms of the benzene ring in styrene are substituted with an alkyl group, one in which some hydrogen atoms of the vinyl group in styrene are substituted with an alkyl group, vinyltoluene, α-methylstyrene, butylstyrene, dimethylstyrene, and isopropenyltoluene. As the styrenic monomer, these may be used singly or in combination of two or more kinds thereof. The other copolymerizable monomer is not particularly limited, and examples thereof include olefins such as α-pinene, β-pinene, and dipentene, unconjugated dienes such as 1,4-hexadiene and 3-methyl-1,4-hexadiene, and conjugated dienes such as 1,3-butadiene and 2-methyl-1,3-butadiene (isoprene). As the other copolymerizable monomer, these may be used singly or in combination of two or more kinds thereof.

As the styrenic copolymer, conventionally known ones can be widely used, the styrenic copolymer is not particularly limited, and examples thereof include a copolymer (preferably, block copolymer) having a structural unit represented by the following Formula (24) (the structure derived from the styrenic monomer) in the molecule.

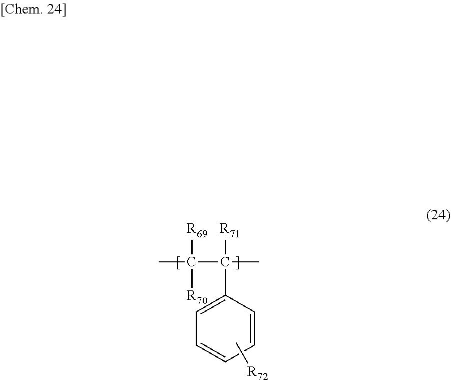

In Formula (24), R₆₉ to R₇₁ each independently represent a hydrogen atom or an alkyl group, and R₇₂ represents any group selected from the group consisting of a hydrogen atom, an alkyl group, an alkenyl group, and an isopropenyl group. The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group. The alkenyl group is preferably an alkenyl group having 1 to 10 carbon atoms.

The styrenic copolymer preferably contains at least one structural unit represented by Formula (24), and may contain two or more different structural units in combination. The styrenic copolymer may contain a structure in which the structural unit represented by Formula (24) is repeated.

The styrenic copolymer may have at least one among structural units represented by the following Formulas (25) to (27) as the structural unit derived from another monomer copolymerizable with the styrenic monomer in addition to the structural unit represented by Formula (24). The structural unit derived from another monomer copolymerizable with the styrenic monomer may have a structure in which each of the structural units represented by the following Formulas (25) to (27) is repeated.

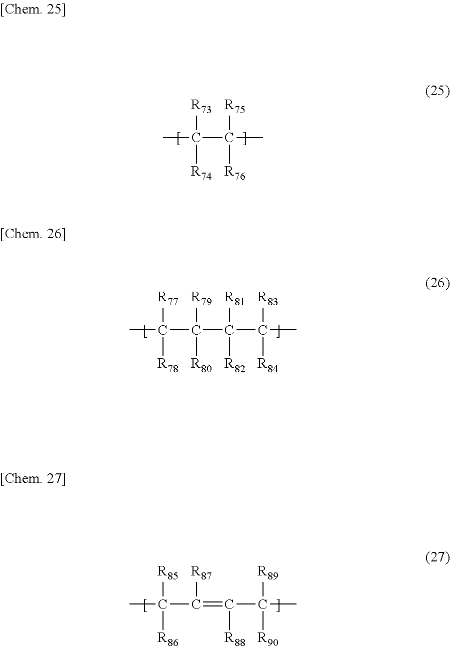

In Formulas (25) to (27), R₇₃ to R₉₀ each independently represent any group selected from the group consisting of a hydrogen atom, an alkyl group, an alkenyl group, and an isopropenyl group. The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group. The alkenyl group is preferably an alkenyl group having 1 to 10 carbon atoms.

The styrenic copolymer preferably contains at least one structural unit represented by Formulas (25) to (27), and may contain two or more different structural units in combination. The styrenic copolymer may contain a structure in which the structural unit represented by Formulas (25) to (27) is repeated.

More specific examples of the structural unit represented by Formula (24) include structural units represented by the following Formulas (28) to (30). The structural unit represented by Formula (24) may be structures in which structural units represented by the following Formulas (28) to (30) are each repeated, and the like. The structural unit represented by Formula (24) may be one structural unit among them or a combination of two or more different structural units.

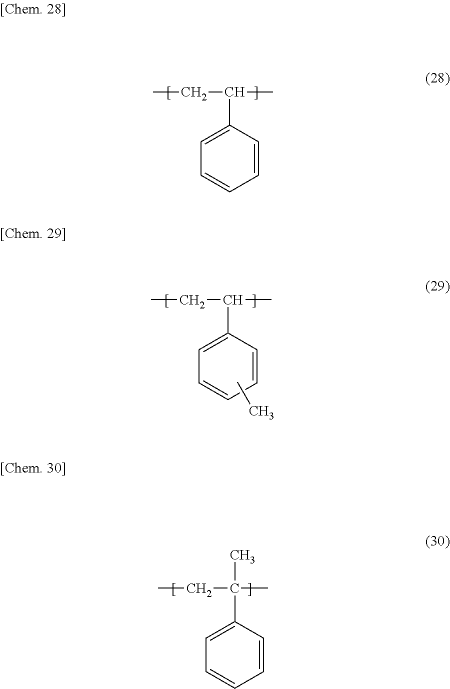

More specific examples of the structural unit represented by Formula (25) include structural units represented by the following Formulas (31) to (37). The structural unit represented by Formula (25) may be structures in which structural units represented by the following Formulas (31) to (37) are each repeated, and the like. The structural unit represented by Formula (25) may be one structural unit among them or a combination of two or more different structural units.

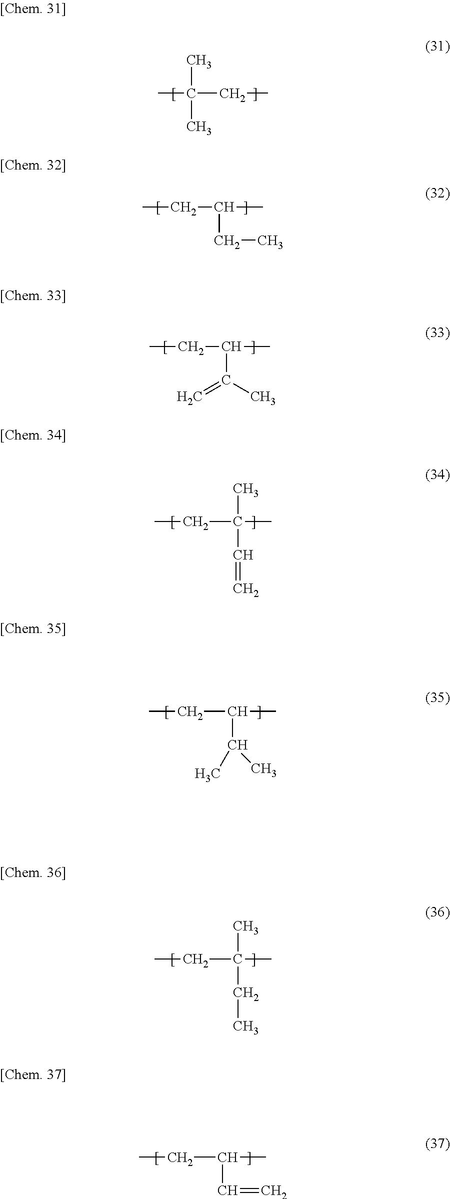

More specific examples of the structural unit represented by Formula (26) include structural units represented by the following Formulas (38) and (39). The structural unit represented by Formula (26) may be structures in which structural units represented by the following Formulas (38) and (39) are each repeated, and the like. The structural unit represented by Formula (26) may be one structural unit among them or a combination of two or more different structural units.

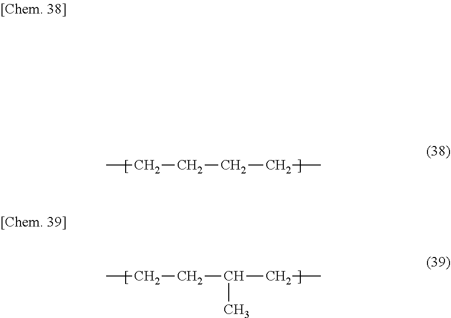

More specific examples of the structural unit represented by Formula (27) include structural units represented by the following Formulas (40) and (41). The structural unit represented by Formula (27) may be structures in which structural units represented by the following Formulas (40) and (41) are each repeated, and the like. The structural unit represented by Formula (27) may be one structural unit among them or a combination of two or more different structural units.

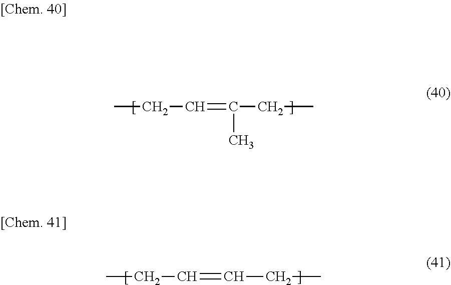

Preferred examples of the styrenic copolymer include copolymers obtained by copolymerizing one or more styrenic monomers such as styrene, vinyltoluene, α-methylstyrene, isopropenyltoluene, divinylbenzene, or allylstyrene. More specific examples of the styrenic copolymer include a methylstyrene (ethylene/butylene) methylstyrene block copolymer, a methylstyrene (ethylene-ethylene/propylene) methylstyrene block copolymer, a styrene isoprene block copolymer, a styrene isoprene styrene block copolymer, a styrene (ethylene/butylene) styrene block copolymer, a styrene (ethylene-ethylene/propylene) styrene block copolymer, a styrene butadiene styrene block copolymer, a styrene (butadiene/butylene) styrene block copolymer, and a styrene isobutylene styrene block copolymer. Examples of the hydrogenated styrenic copolymer include hydrogenated products of the styrenic copolymers. More specific examples of the hydrogenated styrenic copolymer include a hydrogenated methylstyrene (ethylene/butylene) methylstyrene block copolymer, a hydrogenated methylstyrene (ethylene-ethylene/propylene) methylstyrene block copolymer, a hydrogenated styrene isoprene block copolymer, a hydrogenated styrene isoprene styrene block copolymer, a hydrogenated styrene (ethylene/butylene) styrene block copolymer, and a hydrogenated styrene (ethylene-ethylene/propylene) styrene block copolymer.

As the styrenic copolymer, the styrenic copolymers exemplified above may be used singly or in combination of two or more kinds thereof.

In a case where the styrenic copolymer contains at least one among the structural units represented by Formulas (28) to (30), the mass fraction (namely, the content of the structural unit derived from styrene) is preferably about 10% to 60%, more preferably about 20% to 40% with respect to the entire polymer. Therefore, there is an advantage that superior dielectric properties are also attained when the resin composition is cured while favorable compatibility with the radical-polymerizable compound is maintained.

The weight average molecular weight of the styrenic copolymer is preferably 10,000 to 200,000, more preferably 50,000 to 180,000. When the molecular weight is too low, the glass transition temperature or heat resistance of the cured product of the resin composition tends to decrease. When the molecular weight is too high, the viscosity of the resin composition when prepared in the form of a varnish and the viscosity of the resin composition during heat molding tend to be too high. When the molecular weight is in the above range, there is an advantage that it is possible to ensure proper resin fluidity in the resin composition or a semi-cured state (B stage) of the resin composition. The weight average molecular weight is only required to be one measured by a general molecular weight measurement method, and specific examples thereof include a value measured by gel permeation chromatography (GPC).

The styrenic copolymer is preferably a styrenic copolymer having a hardness of 20 to 100, and is preferably a styrenic copolymer having a hardness of 30 to 80. By containing a styrenic copolymer of which the hardness is in the above range, it is considered that a resin composition is obtained which becomes a cured product exhibiting lower dielectric properties and a lower coefficient of thermal expansion when cured.

The hardness includes, for example, durometer hardness, more specifically durometer hardness measured using a type A durometer conforming to JIS K 6253.

As the styrenic copolymer, a commercially available product can be used, and for example, SEPTON V9827, SEPTON V9461, SEPTON 2002, SEPTON 2063, SEPTON 8007L, and HYBRAR 7125F manufactured by KURARAY CO., LTD., FTR 2140 and FTR 6125 manufactured by Mitsui Chemicals, Inc., Dynaron 9901P manufactured by JSR Corporation, Tuftec H1041, Tuftec H1052, and Tuftec H1053 manufactured by Asahi Kasei Corporation, and the like may be used.

### (Flame Retardant)

The resin composition may contain a flame retardant other than the phosphoric acid ester compound (B). Examples of the flame retardant include a compatible phosphorus compound (compatible phosphorus compound compatible with the radical-polymerizable compound (A)) other than the phosphoric acid ester compound (B), and a non-compatible phosphorus compound (C) not compatible with the radical-polymerizable compound (A). The resin composition preferably further contains the non-compatible phosphorus compound (C). That is, the resin composition preferably contains the phosphoric acid ester compound (B) and the non-compatible phosphorus compound (C) as compounds capable of acting as a flame retardant.

### (Compatible Phosphorus Compound)

The compatible phosphorus compound is not particularly limited as long as it is a phosphorus compound that acts as a flame retardant and is compatible with the mixture, and is a compound other than the phosphoric acid ester compound (B). Here, the term “compatible” refers to a state where the phosphorus compound is finely dispersed, for example, at a molecular level in the radical-polymerizable compound (A). Examples of the compatible phosphorus compound include a compound containing phosphorus and not forming a salt, such as a phosphoric acid ester compound, a phosphazene compound, a phosphorous acid ester compound, and a phosphine compound. Examples of the phosphazene compound include cyclic or linear chain phosphazene compounds. The cyclic phosphazene compound, which is also called cyclophosphazene, is a compound having a double bond of phosphorus and nitrogen as constituent elements in the molecule, and having a cyclic structure. Examples of the phosphoric acid ester compound include triphenyl phosphate, tricresyl phosphate, xylenyl diphenyl phosphate, cresyl diphenyl phosphate, 1,3-phenylene bis(di-2,6-xylenyl phosphate), 9,10-dihydro-9-oxa-10-phosphaphenanthrene-10-oxide (DOPO), condensed phosphoric acid ester compounds such as aromatic condensed phosphoric acid ester compounds, and cyclic phosphoric acid ester compounds. Examples of the phosphorous acid ester compound include trimethyl phosphite and triethyl phosphite. Examples of the phosphine compound include tris-(4-methoxyphenyl)phosphine and triphenylphosphine. In addition, the compatible phosphorus compounds may be used singly or in combination of two or more thereof.

### (Non-Compatible Phosphorus Compound)

The non-compatible phosphorus compound is not particularly limited as long as it is a non-compatible phosphorus compound acting as a flame retardant and not compatible with the mixture. Herein, the term “non-compatible” refers to a state where the object (phosphorus compound) is not compatible in the radical-polymerizable compound (A), and is dispersed like islands in the mixture. Examples of the non-compatible phosphorus compound include a compound containing phosphorus and forming a salt, such as a phosphinate compound, a polyphosphoric acid ester compound, and a phosphonium salt compound, and a phosphine oxide compound. Examples of the phosphinate compound include aluminum dialkylphosphinate, aluminum tris(diethylphosphinate), aluminum tris(methylethylphosphinate), aluminum trisdiphenylphosphinate, zinc bisdiethylphosphinate, zinc bismethylethylphosphinate, zinc bisdiphenylphosphinate, titanyl bisdiethylphosphinate, titanyl bismethylethylphosphinate, and titanyl bisdiphenylphosphinate. Examples of the polyphosphoric acid ester compound include melamine polyphosphate, melam polyphosphate, and melem polyphosphate. Examples of the phosphonium salt compound include tetraphenylphosphonium tetraphenylborate, and tetraphenylphosphonium bromide. Examples of the phosphine oxide compound include phosphine oxide compounds (diphenylphosphine oxide compounds) having two or more diphenylphosphine oxide groups in the molecule, and more specifically include paraxylylene bisdiphenylphosphine oxide. In addition, these non-compatible phosphorus compounds may be used singly or in combination of two or more thereof.

The content of the non-compatible phosphorus compound (C) is preferably 30 to 90% by mass, and more preferably 50 to 70% by mass, with respect to a total mass of the phosphoric acid ester compound (B) and the non-compatible phosphorus compound (C). The content of the phosphoric acid ester compound (B) is preferably 10 to 70% by mass, and more preferably 30 to 50% by mass, with respect to the total mass of the phosphoric acid ester compound (B) and the non-compatible phosphorus compound (C).

### (Inorganic Filler)

The resin composition may contain an inorganic filler or may not contain an inorganic filler, and preferably contains an inorganic filler. The inorganic filler is not particularly limited as long as it is an inorganic filler that can be used as an inorganic filler contained in a resin composition. Examples of the inorganic filler include metal oxides such as silica, alumina, titanium oxide, magnesium oxide and mica, metal hydroxides such as magnesium hydroxide and aluminum hydroxide, tale, aluminum borate, barium sulfate, aluminum nitride, boron nitride, barium titanate, magnesium carbonate such as anhydrous magnesium carbonate, and calcium carbonate. Among them, silica, metal hydroxides such as magnesium hydroxide and aluminum hydroxide, aluminum oxide, boron nitride, and barium titanate are preferable, and silica is more preferable. The silica is not particularly limited, and examples thereof include crushed silica, spherical silica, and silica particles.

The inorganic filler may be an inorganic filler subjected to a surface treatment or an inorganic filler not subjected to a surface treatment. Examples of the surface treatment include treatment with a silane coupling agent.

Examples of the silane coupling agent include a silane coupling agent having at least one functional group selected from the group consisting of a vinyl group, a styryl group, a methacryloyl group, an acryloyl group, a phenylamino group, an isocyanurate group, a ureido group, a mercapto group, an isocyanate group, an epoxy group, and an acid anhydride group. In other words, examples of this silane coupling agent include compounds having at least one of a vinyl group, a styryl group, a methacryloyl group, an acryloyl group, a phenylamino group, an isocyanurate group, a ureido group, a mercapto group, an isocyanate group, an epoxy group, or an acid anhydride group as a reactive functional group, and further a hydrolyzable group such as a methoxy group or an ethoxy group.

Examples of the silane coupling agent include vinyltriethoxysilane and

vinyltrimethoxysilane as those having a vinyl group. Examples of the silane coupling agent include p-styryltrimethoxysilane and p-styryltriethoxysilane as those having a styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as those having a methacryloyl group. Examples of the silane coupling agent include 3-acryloxypropyltrimethoxysilane and 3-acryloxypropyltriethoxysilane as those having an acryloyl group. Examples of the silane coupling agent include N-phenyl-3-aminopropyltrimethoxysilane and N-phenyl-3-aminopropyltriethoxysilane as those having a phenylamino group.

The average particle size of the inorganic filler is not particularly limited, and is preferably 0.05 to 10 μm, more preferably 0.1 to 8 μm. Here, the average particle size refers to the volume average particle size. The volume average particle size can be measured by, for example, a laser diffraction method and the like.

The resin composition may contain an inorganic filler as described above. In a case where the resin composition contains the inorganic filler, the content of the inorganic filler is preferably 10 to 250 parts by mass, more preferably 40 to 200 parts by mass, with respect to 100 parts by mass of the radical-polymerizable compound (A).

### (Other Components)

The resin composition may contain components (other components) other than the radical-polymerizable compound (A) and the phosphoric acid ester compound (B), as long as the effects of the present invention are not impaired. As described above, the resin composition may contain a styrenic copolymer, a flame retardant (flame retardant other than the phosphoric acid ester compound (B)), and an inorganic filler as the other components. Examples of the other components other than the styrenic copolymer, the flame retardant, and the inorganic filler include additives such as a reaction initiator, a reaction accelerator, a catalyst, a polymerization retarder, a polymerization inhibitor, a dispersant, a leveling agent, a coupling agent, an antifoaming agent, an antioxidant, a heat stabilizer, an antistatic agent, an ultraviolet absorber, a dye or a pigment, and a lubricant.

As described above, the resin composition according to the present embodiment may contain a reaction initiator. The reaction initiator is not particularly limited as long as it can promote the curing reaction of the resin composition, and examples thereof include a peroxide and an organic azo compound. Examples of the peroxide include α,α′-bis(t-butylperoxy-m-isopropyl)benzene, 2,5-dimethyl-2,5-di(t-butylperoxy)-3-hexyne, and benzoyl peroxide. Examples of the organic azo compound include azobisisobutyronitrile. A metal carboxylate can be concurrently used if necessary. By doing so, the curing reaction can be further promoted. Among them, α,α′-bis(t-butylperoxy-m-isopropyl)benzene is preferably used. α,α′-Bis(t-butylperoxy-m-isopropyl)benzene has a relatively high reaction initiation temperature and thus can suppress the promotion of the curing reaction at the time point at which curing is not required, for example, at the time of prepreg drying, and can suppress a decrease in storage stability of the resin composition. α,α′-Bis(t-butylperoxy-m-isopropyl)benzene exhibits low volatility, thus does not volatilize at the time of prepreg drying and storage, and exhibits favorable stability. Further, the reaction initiators may be used singly or in combination of two or more of thereof.

As described above, the resin composition according to the present embodiment may contain a silane coupling agent. The silane coupling agent may be contained in the resin composition or may be contained as a silane coupling agent covered on the inorganic filler contained in the resin composition for surface treatment in advance. Among them, it is preferable that the silane coupling agent is contained as a silane coupling agent covered on the inorganic filler for surface treatment in advance, and it is more preferable that the silane coupling agent is contained as a silane coupling agent covered on the inorganic filler for surface treatment in advance and further is also contained in the resin composition. In the case of a prepreg, the silane coupling agent may be contained in the prepreg as a silane coupling agent covered on the fibrous base material for surface treatment in advance. Examples of the silane coupling agent include those similar to the silane coupling agents used in the surface treatment of the inorganic filler described above.

### (Use)

The resin composition is used when a prepreg is manufactured, as described later. The resin composition is used when a resin layer included in a metal foil with resin and a film with resin is formed and when an insulating layer included in a metal-clad laminate and a wiring board is formed.

### (Production Method)

The method for producing the resin composition is not particularly limited, and examples thereof include a method in which the radical-polymerizable compound (A) and the phosphoric acid ester compound (B) are mixed together so as to have predetermined contents. Examples thereof include the method to be described later in the case of obtaining a varnish-like composition containing an organic solvent.

By using the resin composition according to the present embodiment, a prepreg, a metal-clad laminate, a wiring board, a metal foil with resin, and a film with resin can be obtained as described below.

### [Prepreg]

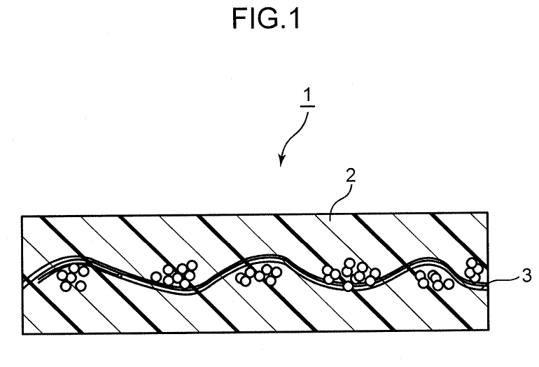

FIG. 1 is a schematic cross-sectional view showing an example of a prepreg 1 according to an embodiment of the present invention.

As shown in FIG. 1, the prepreg 1 according to the present embodiment includes the resin composition or a semi-cured product 2 of the resin composition, and a fibrous base material 3. This prepreg 1 includes the resin composition or the semi-cured product 2 of the resin composition and the fibrous base material 3 present in the resin composition or the semi-cured product 2 of the resin composition.

In the present embodiment, the semi-cured product is in a state in which the resin composition has been cured to an extent that the resin composition can be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, as the semi-curing, the state between the beginning of the viscosity rise and before the complete curing can be mentioned.

The prepreg to be obtained using the resin composition according to the present embodiment may include a semi-cured product of the resin composition as described above or include the uncured resin composition itself. In other words, the prepreg may be a prepreg including a semi-cured product of the resin composition (the resin composition in B stage) and a fibrous base material or a prepreg including the resin composition before being cured (the resin composition in A stage) and a fibrous base material. The resin composition or a semi-cured product of the resin composition may be one obtained by drying or heating and drying the resin composition.

When a prepreg is manufactured, the resin composition 2 is often prepared in a varnish form and used in order to be impregnated into the fibrous base material 3 which is a base material for forming the prepreg. In other words, the resin composition 2 is usually a resin varnish prepared in a varnish form in many cases. Such a varnish-like resin composition (resin varnish) is prepared, for example, as follows.

First, the respective components which can be dissolved in an organic solvent are introduced into and dissolved in an organic solvent. In this case, heating may be performed as necessary. Thereafter, components which are used if necessary but are not dissolved in the organic solvent are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the polyphenylene ether compound, the curing agent, and the like, and does not inhibit the curing reaction. Specific examples thereof include toluene and methyl ethyl ketone (MEK).

Specific examples of the fibrous base material include glass cloth, aramid cloth, polyester cloth, a glass nonwoven fabric, an aramid nonwoven fabric, a polyester nonwoven fabric, pulp paper, and linter paper. When glass cloth is used, a laminate exhibiting excellent mechanical strength is obtained, and glass cloth subjected to flattening is particularly preferable. Specific examples of the flattening include a method in which glass cloth is continuously pressed at an appropriate pressure using a press roll to flatly compress the yarn. The thickness of the generally used fibrous base material is, for example, 0.01 mm or more and 0.3 mm or less. The glass fiber constituting the glass cloth is not particularly limited, and examples thereof include Q glass, NE glass, E glass, S glass, T glass, L glass, and L2 glass. The surface of the fibrous base material may be subjected to a surface treatment with a silane coupling agent. The silane coupling agent is not particularly limited, and examples thereof include a silane coupling agent having at least one selected from the group consisting of a vinyl group, an acryloyl group, a methacryloyl group, a styryl group, an amino group, and an epoxy group in the molecule.

The method for manufacturing the prepreg is not particularly limited as long as the prepreg can be manufactured. Specifically, when the prepreg is manufactured, the resin composition according to the present embodiment described above is often prepared in a varnish form and used as a resin varnish as described above.

Specific examples of the method for manufacturing the prepreg 1 include a method in which the fibrous base material 3 is impregnated with the resin composition 2, for example, the resin composition 2 prepared in a varnish form, and then dried. The fibrous base material 3 is impregnated with the resin composition 2 by dipping, coating, and the like. If necessary, the impregnation can be repeated a plurality of times. In this case, it is also possible to finally adjust the desired composition and impregnation amount by repeating impregnation using a plurality of resin compositions having different compositions and concentrations.

The fibrous base material 3 impregnated with the resin composition (resin varnish) 2 is heated under desired heating conditions, for example, at 40° C. or more and 180° C. or less for 1 minute or more and 10 minutes or less. By heating, the prepreg 1 before being cured (A-stage) or in a semi-cured state (B-stage) is obtained. By the heating, the organic solvent can be decreased or removed by being volatilized from the resin varnish.

The resin composition according to the present embodiment is a resin composition, which affords a cured product having a low relative dielectric constant and a low dielectric loss tangent, being excellent in flame retardancy and interlayer adhesion, and having a high glass transition temperature. For this reason, the prepreg including this resin composition or a semi-cured product of this resin composition is a prepreg, which affords a cured product having a low relative dielectric constant and a low dielectric loss tangent, being excellent in flame retardancy and interlayer adhesion, and having a high glass transition temperature. Moreover, a wiring board including an insulating layer containing a cured product having a low relative dielectric constant and a low dielectric loss tangent, being excellent in flame retardancy and interlayer adhesion, and having a high glass transition temperature can be suitably manufactured using this prepreg.

### [Metal-Clad Laminate]

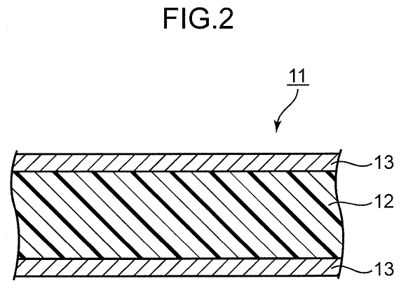

FIG. 2 is a schematic cross-sectional view showing an example of a metal-clad laminate 11 according to the embodiment of the present invention.

As shown in FIG. 2, the metal-clad laminate 11 according to the present embodiment includes an insulating layer 12 containing a cured product of the resin composition and a metal foil 13 provided on the insulating layer 12. Examples of the metal-clad laminate 11 include a metal-clad laminate including an insulating layer 12 containing a cured product of the prepreg 1 shown in FIG. 1 and a metal foil 13 to be laminated together with the insulating layer 12. The insulating layer 12 may be formed of a cured product of the resin composition or a cured product of the prepreg. In addition, the thickness of the metal foil 13 varies depending on the performance and the like to be required for the finally obtained wiring board and is not particularly limited. The thickness of the metal foil 13 can be appropriately set depending on the desired purpose and is preferably, for example, 0.2 to 70 μm. Examples of the metal foil 13 include a copper foil and an aluminum foil, and the metal foil 13 may be a copper foil with carrier which includes a release layer and a carrier for the improvement in handleability in a case where the metal foil is thin.

The method for manufacturing the metal-clad laminate 11 is not particularly limited as long as the metal-clad laminate 11 can be manufactured. Specific examples thereof include a method in which the metal-clad laminate 11 is fabricated using the prepreg 1. Examples of this method include a method in which the double-sided metal foil-clad or single-sided metal foil-clad laminate 11 is fabricated by stacking one sheet or a plurality of sheets of prepreg 1, further stacking the metal foil 13 such as a copper foil on both or one of upper and lower surfaces of the prepregs 1, and laminating and integrating the metal foils 13 and prepregs 1 by heating and pressing. In other words, the metal-clad laminate 11 is obtained by laminating the metal foil 13 on the prepreg 1 and then performing heating and pressing. The heating and pressing conditions can be appropriately set depending on the thickness of the metal-clad laminate 11, the kind of the resin composition contained in the prepreg 1, and the like. For example, it is possible to set the temperature to 170° ° C. to 230° C., the pressure to 2 to 4 MPa, and the time to 60 to 150 minutes. Moreover, the metal-clad laminate may be manufactured without using a prepreg. Examples thereof include a method in which a varnish-like resin composition is applied on a metal foil to form a layer containing the resin composition on the metal foil and then heating and pressing is performed.

The resin composition according to the present embodiment is a resin composition, which affords a cured product having a low relative dielectric constant and a low dielectric loss tangent, being excellent in flame retardancy and interlayer adhesion, and having a high glass transition temperature. For this reason, the metal-clad laminate including an insulating layer containing a cured product of this resin composition is a metal-clad laminate including an insulating layer containing a cured product having a low relative dielectric constant and a low dielectric loss tangent, being excellent in flame retardancy and interlayer adhesion, and having a high glass transition temperature. Moreover, a wiring board including an insulating layer containing a cured product having a low relative dielectric constant and a low dielectric loss tangent, being excellent in flame retardancy and interlayer adhesion, and having a high glass transition temperature can be suitably manufactured using this metal-clad laminate.

### [Wiring Board]

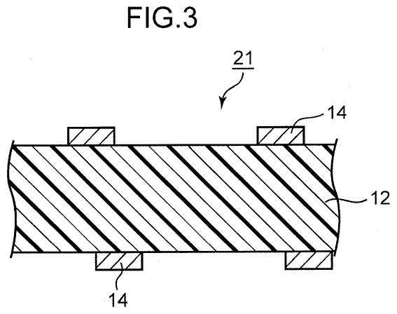

FIG. 3 is a schematic cross-sectional view showing an example of a wiring board 21 according to the embodiment of the present invention.

As shown in FIG. 3, the wiring board 21 according to the present embodiment includes an insulating layer 12 containing a cured product of the resin composition and wiring 14 provided on the insulating layer 12. Examples of the wiring board 21 include a wiring board formed of an insulating layer 12 obtained by curing the prepreg 1 shown in FIG. 1 and wiring 14 which is laminated together with the insulating layer 12 and is formed by partially removing the metal foil 13. The insulating layer 12 may be formed of a cured product of the resin composition or a cured product of the prepreg.

The method for manufacturing the wiring board 21 is not particularly limited as long as the wiring board 21 can be manufactured. Specific examples thereof include a method in which the wiring board 21 is fabricated using the prepreg 1. Examples of this method include a method in which the wiring board 21, in which wiring is provided as a circuit on the surface of the insulating layer 12, is fabricated by forming wiring through etching and the like of the metal foil 13 on the surface of the metal-clad laminate 11 fabricated in the manner described above. In other words, the wiring board 21 is obtained by partially removing the metal foil 13 on the surface of the metal-clad laminate 11 and thus forming a circuit. Examples of the method for forming a circuit include circuit formation by a semi-additive process (SAP) or a modified semi-additive process (MSAP) in addition to the method described above.

The wiring board 21 is a wiring board including the insulating layer 12 containing a cured product having a low relative dielectric constant and a low dielectric loss tangent, being excellent in flame retardancy and interlayer adhesion, and having a high glass transition temperature.

[Metal Foil with Resin]

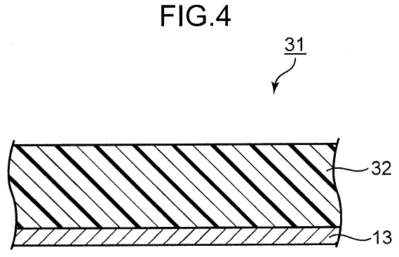

FIG. 4 is a schematic cross-sectional view showing an example of a metal foil with resin 31 according to the present embodiment.

The metal foil with resin 31 according to the present embodiment includes a resin layer 32 containing the resin composition or a semi-cured product of the resin composition and a metal foil 13 as shown in FIG. 4. The metal foil with resin 31 includes the metal foil 13 on the surface of the resin layer 32. In other words, the metal foil with resin 31 includes the resin layer 32 and the metal foil 13 to be laminated together with the resin layer 32. Furthermore, the metal foil with resin 31 with a resin may have another layer between the resin layer 32 and the metal foil 13.

The resin layer 32 may contain a semi-cured product of the resin composition as described above or may contain the uncured resin composition. In other words, the metal foil with resin 31 may be a metal foil with resin including a resin layer containing a semi-cured product of the resin composition (the resin composition in B stage) and a metal foil or a metal foil with resin including a resin layer containing the resin composition before being cured (the resin composition in A stage) and a metal foil. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the metal foil, metal foils used in metal-clad laminates or metal foils with resin can be used without limitation. Examples of the metal foil include a copper foil and an aluminum foil.

The metal foil with resin 31 may include a cover film and the like if necessary. By including a cover film, it is possible to prevent entry of foreign matter and the like. The cover film is not particularly limited, and examples thereof include a polyolefin film, a polyester film, a polymethylpentene film, and films formed by providing a release agent layer on these films.

The method for manufacturing the metal foil with resin 31 is not particularly limited as long as the metal foil with resin 31 can be manufactured. Examples of the method for manufacturing the metal foil with resin 31 include a method in which the varnish-like resin composition (resin varnish) is applied on the metal foil 13 and heated to manufacture the metal foil with resin 31. The varnish-like resin composition is applied on the metal foil 13 using, for example, a bar coater. The applied resin composition is heated under the conditions of, for example, 40° C. or more and 180° C. or less and 0.1 minute or more and 10 minutes or less. The heated resin composition is formed as the uncured resin layer 32 on the metal foil 13. By the heating, the organic solvent can be decreased or removed by being volatilized from the resin varnish.

The resin composition according to the present embodiment is a resin composition, which affords a cured product having a low relative dielectric constant and a low dielectric loss tangent, being excellent in flame retardancy and interlayer adhesion, and having a high glass transition temperature. For this reason, the metal foil with resin including a resin layer containing this resin composition or a semi-cured product of this resin composition is a metal foil with resin including a resin layer, which affords a cured product having a low relative dielectric constant and a low dielectric loss tangent, being excellent in flame retardancy and interlayer adhesion, and having a high glass transition temperature. Moreover, the metal foil with resin can be used when manufacturing a wiring board including an insulating layer containing a cured product having a low relative dielectric constant and a low dielectric loss tangent, being excellent in flame retardancy and interlayer adhesion, and having a high glass transition temperature. For example, by laminating the metal foil with resin on a wiring board, a multilayer wiring board can be manufactured. As a wiring board obtained using such a metal foil with resin, there is obtained a wiring board including an insulating layer containing a cured product having a low relative dielectric constant and a low dielectric loss tangent, being excellent in flame retardancy and interlayer adhesion, and having a high glass transition temperature.

[Film with Resin]

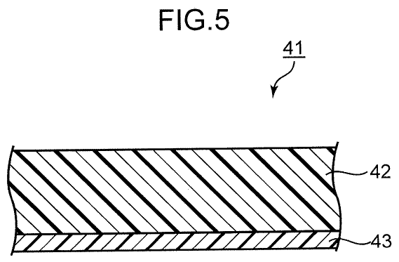

FIG. 5 is a schematic sectional view showing an example of a film with resin 41 according to the present embodiment.

The film with resin 41 according to the present embodiment includes a resin layer 42 containing the resin composition or a semi-cured product of the resin composition and a support film 43 as shown in FIG. 5. The film with resin 41 includes the resin layer 42 and the support film 43 to be laminated together with the resin layer 42. In addition, the film with resin 41 may have another layer between the resin layer 42 and the support film 43.

The resin layer 42 may contain a semi-cured product of the resin composition as described above or may contain the uncured resin composition. In other words, the film with resin 41 may be a film with resin including a resin layer containing a semi-cured product of the resin composition (the resin composition in B stage) and a support film or a film with resin including a resin layer containing the resin composition before being cured (the resin composition in A stage) and a support film. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, the same fibrous base material as that of the prepreg can be used.

As the support film 43, support films used in films with resin can be used without limitation. Examples of the support film include electrically insulating films such as a polyester film, a polyethylene terephthalate (PET) film, a polyimide film, a polyparabanic acid film, a polyether ether ketone film, a polyphenylene sulfide film, a polyamide film, a polycarbonate film, and a polyarylate film.

The film with resin 41 may include a cover film and the like if necessary. By including a cover film, it is possible to prevent entry of foreign matter and the like. The cover film is not particularly limited, and examples thereof include a polyolefin film, a polyester film, and a polymethylpentene film.

The support film and the cover film may be those subjected to surface treatments such as a matt treatment, a corona treatment, a release treatment, and a roughening treatment if necessary.

The method for manufacturing the film with resin 41 is not particularly limited as long as the film with resin 41 can be manufactured. Examples of the method for manufacturing the film with resin 41 include a method in which the varnish-like resin composition (resin varnish) is applied on the support film 43 and heated to manufacture the film with resin 41. The varnish-like resin composition is applied on the support film 43 using, for example, a bar coater. The applied resin composition is heated under the conditions of, for example, 40° C. or more and 180° C. or less and 0.1 minute or more and 10 minutes or less. The heated resin composition is formed as the uncured resin layer 42 on the support film 43. By the heating, the organic solvent can be decreased or removed by being volatilized from the resin varnish.

The resin composition according to the present embodiment is a resin composition, which affords a cured product having a low relative dielectric constant and a low dielectric loss tangent, being excellent in flame retardancy and interlayer adhesion, and having a high glass transition temperature. For this reason, the film with resin including a resin layer containing this resin composition or a semi-cured product of this resin composition is a film with resin including a resin layer, which affords a cured product having a low relative dielectric constant and a low dielectric loss tangent, being excellent in flame retardancy and interlayer adhesion, and having a high glass transition temperature. Moreover, the film with resin can be used when suitably manufacturing a wiring board including an insulating layer containing a cured product having a low relative dielectric constant and a low dielectric loss tangent, being excellent in flame retardancy and interlayer adhesion, and having a high glass transition temperature. A multilayer wiring board can be manufactured, for example, by laminating the film with resin on a wiring board and then peeling off the support film from the film with resin or by peeling off the support film from the film with resin and then laminating the film with resin on a wiring board. As a wiring board obtained using such a film with resin, there is obtained a wiring board including an insulating layer containing a cured product having a low relative dielectric constant and a low dielectric loss tangent, being excellent in flame retardancy and interlayer adhesion, and having a high glass transition temperature.

According to the present invention, it is possible to provide a resin composition, which affords a cured product having a low relative dielectric constant and a low dielectric loss tangent, being excellent in flame retardancy and interlayer adhesion, and having a high glass transition temperature. Furthermore, according to the present invention, it is possible to provide a prepreg, a film with resin, a metal foil with resin, a metal-clad laminate, and a wiring board each obtained using the resin composition.

Hereinafter, the present invention will be described more specifically with reference to Examples, but the scope of the present invention is not limited thereto.

### EXAMPLES

### Examples 1 to 8 and Comparative Examples 1 to 7

The respective components used when a resin composition is prepared in the present Examples will be described.

### (Radical-Polymerizable Compound (A): PPE)

Modified PPE-1: Modified polyphenylene ether obtained by modifying terminal hydroxyl group of polyphenylene ether with methacryloyl group (a modified polyphenylene ether compound represented by Formula (14), where Y is a dimethylmethylene group (a group represented by Formula (11), where R₆₃ and R₆₄ are a methyl group), SA9000 manufactured by SABIC Innovative Plastics Co., Ltd., number average molecular weight Mn: 2300, number of terminal functional groups: 2)

Modified PPE-2: Polyphenylene ether compound having vinylbenzyl group (ethenylbenzyl group) at terminal (a modified polyphenylene ether compound obtained by reacting polyphenylene ether with chloromethylstyrene).

Specifically, this is a modified polyphenylene ether compound obtained by conducting a reaction as follows.

First, 200 g of polyphenylene ether (SA90 manufactured by SABIC Innovative Plastics Co., Ltd., number of terminal hydroxyl groups: 2, weight average molecular weight Mw: 1700), 30 g of a mixture containing p-chloromethylstyrene and m-chloromethylstyrene at a mass ratio of 50:50 (chloromethylstyrene: CMS manufactured by Tokyo Chemical Industry Co., Ltd.), 1.227 g of tetra-n-butylammonium bromide as a phase transfer catalyst, and 400 g of toluene were introduced into a 1-liter three-necked flask equipped with a temperature controller, a stirrer, cooling equipment, and a dropping funnel and stirred. Then, the mixture was stirred until polyphenylene ether, chloromethylstyrene, and tetra-n-butylammonium bromide were dissolved in toluene. At that time, the mixture was gradually heated until the liquid temperature finally reached 75° C. Then, an aqueous sodium hydroxide solution (20 g of sodium hydroxide/20 g of water) as an alkali metal hydroxide was added dropwise to the solution over 20 minutes. Thereafter, the mixture was further stirred at 75° C. for 4 hours. Next, the resultant in the flask was neutralized with hydrochloric acid at 10% by mass and then a large amount of methanol was added into the flask. By doing so, a precipitate was generated in the liquid in the flask. In other words, the product contained in the reaction solution in the flask was reprecipitated. Then, this precipitate was taken by filtration and washed three times with a liquid mixture of methanol and water at a mass ratio of 80:20, and then dried at 80° C. under reduced pressure for 3 hours.

The obtained solid was analyzed by 1H-NMR (400 MHZ, CDCl₃, TMS). As a result of NMR measurement, a peak attributed to a vinylbenzyl group (ethenylbenzyl group) was observed at 5 to 7 ppm. This made it possible to confirm that the obtained solid was a modified polyphenylene ether compound having a vinylbenzyl group (ethenylbenzyl group) as the substituent at the molecular terminal in the molecule. Specifically, the obtained solid was confirmed to be ethenylbenzylated polyphenylene ether. This modified polyphenylene ether compound obtained was a modified polyphenylene ether compound represented by Formula (13), where Y was a dimethylmethylene group (a group represented by Formula (11), where R₆₃ and R₆₄ were a methyl group). Ar₃ was a phenylene group, R₃₁ to R₃₃ were hydrogen atoms, and p was 1.

The number of terminal functional groups in the modified polyphenylene ether was measured as follows.

First, the modified polyphenylene ether was accurately weighed. The weight at that time is defined as X (mg). Thereafter, this modified polyphenylene ether weighed was dissolved in 25 mL of methylene chloride, 100 μL of an ethanol solution of tetraethylammonium hydroxide (TEAH) at 10% by mass (TEAH: ethanol (volume ratio)=15:85) was added to the solution, and then the absorbance (Abs) of this mixture at 318 nm was measured using a UV spectrophotometer (UV-1600 manufactured by Shimadzu Corporation). Then, the number of terminal hydroxyl groups in the modified polyphenylene ether was calculated from the measurement results using the following equation.

$$Amount of residual OH ( µmol / g ) = [ ( 25 \times Abs ) / ( ε \times O P L \times X ) ] \times 1 {0}^{6}$$

Here, ε indicates the extinction coefficient and is 4700 L/mol·cm. OPL is an optical path length of 1 cm.

Since the calculated residual OH amount (the number of terminal hydroxyl groups) in the modified polyphenylene ether is almost zero, it was found that the hydroxyl groups in the polyphenylene ether before being modified are almost modified. From this fact, it was found that the number of terminal hydroxyl groups decreased from the number of terminal hydroxyl groups in polyphenylene ether before being modified was the number of terminal hydroxyl groups in polyphenylene ether before being modified. In other words, it was found that the number of terminal hydroxyl groups in polyphenylene ether before being modified was the number of terminal functional groups in the modified polyphenylene ether. In other words, the number of terminal functional groups was 2.

In addition, an intrinsic viscosity (IV) of the modified polyphenylene ether was measured in methylene chloride at 25° C. Specifically, the intrinsic viscosity (IV) of the modified polyphenylene ether was measured in a methylene chloride solution (liquid temperature: 25° C.) of the modified polyphenylene ether at 0.18 g/45 ml using a viscometer (AVS500 Visco System manufactured by SCHOTT Instruments GmbH). As a result, the intrinsic viscosity (IV) of the modified polyphenylene ether was 0.086 dl/g.

The molecular weight distribution of the modified polyphenylene ether was measured by GPC. Moreover, the weight average molecular weight (Mw) was calculated from the obtained molecular weight distribution. As a result, Mw was 1,900.

### (Radical-Polymerizable Compound (A): Curing Agent)

TAIC: Triallyl isocyanurate (TAIC manufactured by Nihon Kasei Co., Ltd.)

DVB: Divinylbenzene (DVB810 manufactured by NIPPON STEEL CORPORATION)

### (Styrenic Copolymer)

8007L: Hydrogenated styrene butadiene copolymer (SEBS) (SEPTON 8007L manufactured by KURARAY CO., LTD.)

H1053: Hydrogenated styrene butadiene copolymer (SEBS) (Tuftec H1053 manufactured by Asahi Kasei Corporation)

### (Compatible Phosphorus Compound)

Phosphoric acid ester compound-1: phosphoric acid ester compound (phosphoric acid ester compound obtained by reacting 3,3,5-trimethyl-1,1-bis(4-hydroxyphenyl)cyclohexane, 2,6-xylenol, and phosphoryl chloride) having alicyclic hydrocarbon structure in molecule.

Specifically, the phosphoric acid ester compound-1 is a phosphoric acid ester compound obtained by conducting a reaction as follows.

### <Synthesis Method of DXPC>

First, dixylylphosphorochloridate (DXPC) was synthesized. Specifically, the dixylylphosphorochloridate was synthesized as follows.

A 2-liter four-necked flask equipped with a stirrer, a thermometer, and a hydrochloric acid recovery device (capacitor to which a water scrubber is connected) was charged with 767 g of phosphoryl chloride (phosphorus oxychloride) (manufactured by Tokyo Chemical Industry Co., Ltd.), 1,200 g of 2,6-xylenol (manufactured by Tokyo Chemical Industry Co., Ltd.), 140 g of xylene as a solvent, and 6.2 g of magnesium chloride as a catalyst.

The liquid in the four-necked flask was heated with stirring, and the liquid temperature was gradually raised to 160° C. over about 3 hours. As a result, the reaction between 2,6-xylenol and phosphoryl chloride proceeded, and hydrogen chloride (hydrochloric acid gas) generated by the reaction was recovered by the water scrubber. Thereafter, the pressure in the flask was gradually reduced to 20 kPa at the same temperature (160° C.) to remove xylene, unreacted phosphoryl chloride, unreacted 2,6-xylenol, and hydrogen chloride produced as a by-product. By doing so, 1,700 g of dixylylphosphorochloridate (DXPC) represented by the following Formula (42) was obtained.

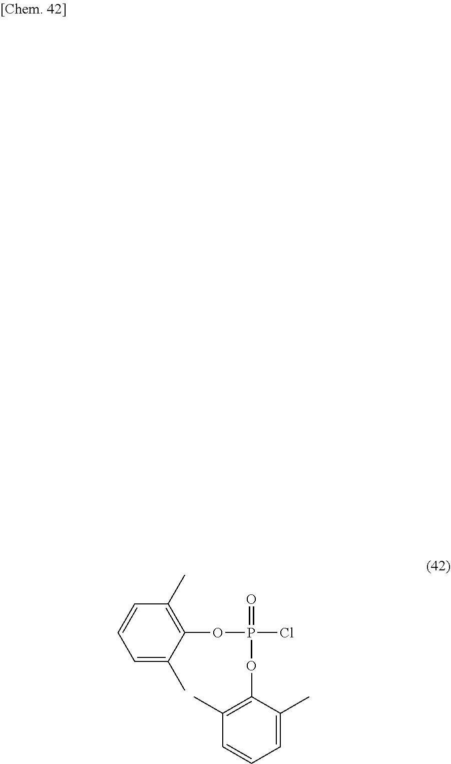 [SMILES: Cc1cccc(C)c1OP(=O)(Cl)Oc1c(C)cccc1C]

### <Synthesis Method of Phosphoric Acid Ester Compound>

Next, a phosphoric acid ester compound having an alicyclic hydrocarbon structure in the molecule (phosphoric acid ester compound represented by Formula (21)) was synthesized using dixylylphosphorochloridate (DXPC) obtained by the DXPC synthesis method. Specifically, the phosphoric acid ester compound was synthesized as follows.

A 2-liter four-necked flask equipped with a stirrer, a thermometer, a dropping funnel, and a capacitor was charged with 460 g of dixylylphosphorochloridate (DXPC) obtained by the DXPC synthesis method, 196 g of 3,3,5-trimethyl-1,1-bis(4-hydroxyphenyl)cyclohexane (BisP-TMC manufactured by Honshu Chemical Industry Co., Ltd.), 540 g of toluene and 140 g of tetrahydrofuran as solvents. The dropping funnel was charged with 151 g of triethylamine as a hydrogen halide scavenger.

The liquid in the four-necked flask was heated while being stirred until the liquid temperature reached 65° C. Thereafter, triethylamine in the dropping funnel was added dropwise over 1 hour and 30 minutes while the same temperature (65° C.) was maintained. After completion of the dropwise addition, the mixture was stirred at the same temperature (65° C.) for 2 hours. The reaction product thus obtained was washed with dilute hydrochloric acid and water, then neutralized with an aqueous sodium hydroxide solution, and washed again with water. Thereafter, the mixture was heated until the liquid temperature reached 110° C., and the pressure was reduced to 1 kPa to recover water, toluene, and tetrahydrofuran. In addition, steam distillation was performed at 110° C. under a reduced pressure of 1 kPa to distill off a low-boiling fraction, and then the mixture was cooled to normal temperature. By doing so, 553 g of a light yellow clear glassy solid was obtained. It was confirmed by 1H-NMR that this obtained product was the phosphoric acid ester compound represented by Formula (21).

Phosphoric acid ester compound-2: Phosphoric acid ester compound having no alicyclic hydrocarbon structure in molecule (PX-200 manufactured by DAIHACHI CHEMICAL INDUSTRY CO., LTD., phosphoric acid ester compound represented by the following Formula (43))

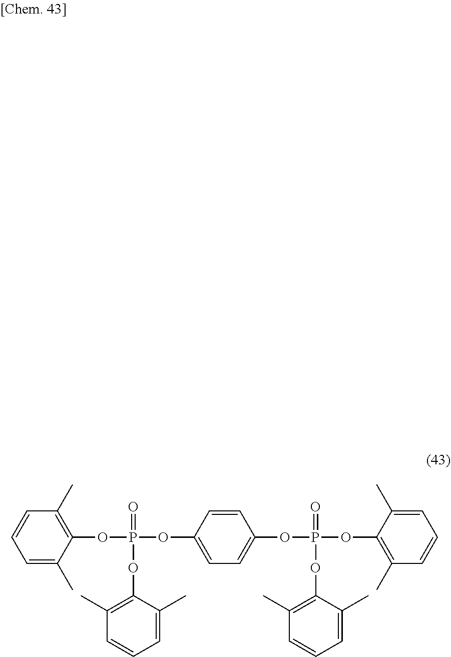 [SMILES: Cc1cccc(C)c1OP(=O)(Oc1ccc(OP(=O)(Oc2c(C)cccc2C)Oc2c(C)cccc2C)cc1)Oc1c(C)cccc1C]

### (Non-Compatible Phosphorus Compound)

Phosphinate compound: Aluminum trisdiethylphosphinate (Exolit OP-935 manufactured by Clariant Japan K. K.)

### (Reaction Initiator)

PERBUTYL P: Peroxide (α,α′-di(t-butylperoxy)diisopropylbenzene, Perbutyl P manufactured by NOF CORPORATION)

### (Inorganic Filler)

Silica: Spherical silica (SC2300-SVJ manufactured by Admatechs Co., Ltd.)

### [Preparation Method]

First, the components other than the inorganic filler were added to and mixed in toluene at the composition (parts by mass) presented in Table 1 so that the solid concentration was 50% by mass. The resulting mixture was stirred for 60) minutes. Thereafter, the inorganic filler was added to the obtained liquid at the composition (parts by mass) presented in Table 1, and dispersed in the liquid using a bead mill. By doing so, a varnish-like resin composition (varnish) was obtained.

Next, a prepreg and an evaluation substrate 1 (metal-clad laminate) were obtained as follows.

The obtained varnish was impregnated into a fibrous base material (glass cloth: #1078 type, L glass manufactured by Asahi Kasei Corporation) and then heated and dried at 120° C. to 150° C. for 3 minutes, thereby fabricating a prepreg. At that time, the content (resin content) of the components constituting the resin composition with respect to the prepreg was adjusted to be 73% to 80% by mass by the curing reaction.

Next, an evaluation substrate 1 (metal-clad laminate) was obtained as follows.

Copper foil (CF-T4X-SV manufactured by Fukuda Metal Foil & Powder Co., Ltd., thickness: 18 μm) was disposed on both sides of each of the obtained prepregs. This as a body to be pressed was heated to a temperature of 220° ° C. at a rate of temperature rise of 3° C./min and heated and pressed under the conditions of 220° C., 90 minutes, and a pressure of 3 MPa, thereby obtaining an evaluation substrate 1 (metal-clad laminate) having a copper foil bonded to both surfaces and a thickness of about 0.13 mm.

The evaluation substrate 1 (metal-clad laminate) fabricated as described above was evaluated by the following methods.

### [Flame Retardancy]

An unclad plate was obtained by removing the copper foil from the evaluation substrate 1 (metal-clad laminate) by etching. A test piece having a length of 125 mm and a width of 12.5 mm was cut out from the unclad plate. Then, the test piece was subjected to a flame test according to “Test for Flammability of Plastic Materials-UL 94” by Underwriters Laboratories. As a result, when the test piece was at “V-0” level, its inflammability was evaluated as “V-0”, and when the test piece was at “HB” level, its inflammability was evaluated as “HB”.

### [Interlayer Adhesion]

An unclad plate was obtained by removing the copper foil from the evaluation substrate 1 (metal-clad laminate) by etching. The unclad board was allowed to absorb moisture by being left at a temperature of 85° C., and a relative humidity of 85% for 168 hours. A laminate (evaluation substrate 2) was obtained by using the unclad plate, which had absorbed moisture, as a core, arranging prepregs on both surfaces of the core, and performing secondary molding. An insulating layer (prepreg) on the uppermost surface of the evaluation substrate 2 was peeled off. At that time, a normal adhesion state of the laminate was evaluated as “O” and when there was a portion in an abnormal adhesion state, the laminate was evaluated as “X”. The normal adhesion state refers to a state where the adhesive strength between the prepregs constituting the laminate (evaluation substrate 2) is high, and when trying to peel off the prepreg on the uppermost surface, peeling does not occur at the interface of the prepregs, but such peeling occurs between the prepreg resin and the glass cloth. Further, the abnormal adhesion state is an adhesion state other than the normal adhesion state. Specifically, for example, the abnormal adhesion state refers to a state where the prepreg peels off at the interface between the prepregs constituting the laminate (evaluation substrate 2) when trying to peel off the prepreg on the uppermost surface.

### [Glass Transition Temperature (Tg)]

Using an unclad substrate obtained by removing the copper foil from the evaluation substrate 1 (metal-clad laminate) by etching as a test piece, the Tg of the unclad plate was measured by a viscoelastic spectrometer “DMS6100” manufactured by Seiko Instruments Inc. At this time, dynamic viscoelasticity measurement (DMA) was performed with a tensile module at a frequency of 1 Hz, and the temperature at which tan 8 was maximized when the temperature was raised from room temperature to 320° C. at a rate of temperature rise of 5° C./min was taken as Tg)(° ° C.

### [Dielectric Properties (Relative Dielectric Constant and Dielectric Loss Tangent]

The relative dielectric constant and dielectric loss tangent at 10 GHz were measured by a cavity perturbation method using an unclad substrate obtained by removing the copper foil from the evaluation substrate 1 (metal-clad laminate) by etching as a test piece. Specifically, the relative dielectric constant and dielectric loss tangent of the evaluation substrate 1 at 10 GHz were measured using a network analyzer (N5230A manufactured by Agilent Technologies, Inc.).

The results of each evaluation are shown in Table 1.

TABLE 1

| | | | | Example | | | | | | | |
|---|---|---|---|---|---|---|---|---|---|---|---|
| | | | | 1 | 2 | 3 | 4 | 5 | 6 | 7 | 8 |
| Composition | Radical- | PPE | Modified | 70 | 70 | — | — | 70 | 70 | 70 | 70 |
| (parts by | polymerizable | | PPE-1 | | | | | | | | |
| mass) | compound | | Modified | — | — | 70 | 70 | — | — | — | — |
| | | | PPE-2 | | | | | | | | |
| | | Curing | TAIC | 30 | 30 | — | — | 30 | 30 | 30 | 30 |
| | | agent | DVB | — | — | 30 | 30 | — | — | — | — |

| | Styrenic | 8007L | — | — | — | — | 20 | — | — | — |
|---|---|---|---|---|---|---|---|---|---|---|
| | copolymer | H1053 | — | — | — | — | — | 20 | — | — |
| | Compatible | Phosphoric | 30 | 45 | 30 | 45 | 45 | 45 | 10 | 15 |
| | phosphorus | acid ester | | | | | | | | |
| | compound | compound-1 | | | | | | | | |
| | | Phosphoric | — | — | — | — | — | — | — | — |
| | | acid ester | | | | | | | | |
| | | compound-2 | | | | | | | | |
| | Non-compatible | Phosphinate | — | — | — | — | — | — | 20 | 30 |
| | phosphorus compound | compound | | | | | | | | |
| | Reaction initiator | Perbutyl P | 1 | 1 | 1 | 1 | 1 | 1 | 1 | 1 |
| | Inorganic filler | Silica | 130 | 130 | 130 | 130 | 130 | 130 | 130 | 130 |
| Evaluation | Flame retardancy | | V-0 | V-0 | V-0 | V-0 | V-0 | V-0 | V-0 | V-0 |
| | Interlayer adhesion | | ◯ | ◯ | ◯ | ◯ | ◯ | ◯ | ◯ | ◯ |
| | Glass transition | | 190 | 170 | 190 | 170 | 170 | 170 | 220 | 210 |
| | temperature (° C.) | | | | | | | | | |
| | Dielectric properties | Relative | 3.2 | 3.2 | 3.2 | 3.2 | 3.2 | 3.2 | 3.3 | 3.3 |
| | | dielectric | | | | | | | | |

| | | | | | | | | |
|---|---|---|---|---|---|---|---|---|
| constant | | | | | | | | |
| Dielectric | 0.0020 | 0.0020 | 0.0022 | 0.0022 | 0.0019 | 0.0019 | 0.0030 | 0.0028 |
| loss | | | | | | | | |
| tangent | | | | | | | | |

| | | | | Comparative Example | | | | | | |
|---|---|---|---|---|---|---|---|---|---|---|
| | | | | 1 | 2 | 3 | 4 | 5 | 6 | 7 |
| Composition | Radical- | PPE | Modified | 70 | 70 | — | — | 70 | 70 | 70 |
| (parts by | polymerizable | | PPE-1 | | | | | | | |
| mass) | compound | | Modified | — | — | 70 | 70 | — | — | — |
| | | | PPE-2 | | | | | | | |
| | | Curing | TAIC | 30 | 30 | — | — | 30 | 30 | 30 |
| | | agent | DVB | — | — | 30 | 30 | — | — | — |

| Styrenic | 8007L | — | — | — | — | — | 20 | — |
|---|---|---|---|---|---|---|---|---|
| copolymer | H1053 | — | — | — | — | — | — | 20 |
| Compatible | Phosphoric | — | — | — | — | — | — | — |
| phosphorus | acid ester | | | | | | | |
| compound | compound-1 | | | | | | | |
| | Phosphoric | 30 | 45 | 30 | 45 | — | 45 | 45 |
| | acid ester | | | | | | | |
| | compound-2 | | | | | | | |
| Non-compatible | Phosphinate | — | — | — | — | — | — | — |
| phosphorus compound | compound | | | | | | | |
| Reaction initiator | Perbutyl P | 1 | 1 | 1 | 1 | 1 | 1 | 1 |
| Inorganic filler | Silica | 130 | 130 | 130 | 130 | 130 | 130 | 130 |

| | | | | | | | | |
|---|---|---|---|---|---|---|---|---|
| Evaluation | Flame retardancy | V-0 | V-0 | V-0 | V-0 | HB | V-0 | V-0 |
| | Interlayer adhesion | X | X | X | X | ◯ | X | X |
| | Glass transition | 170 | 145 | 170 | 145 | 250 | 145 | 145 |
| | temperature (° C.) | | | | | | | |

| | | | | | | | | |
|---|---|---|---|---|---|---|---|---|
| Dielectric properties | Relative | 3.2 | 3.2 | 3.2 | 3.2 | 3.3 | 3.2 | 3.2 |
| | dielectric | | | | | | | |

| | | | | | | | |
|---|---|---|---|---|---|---|---|
| constant | | | | | | | |
| Dielectric | 0.0023 | 0.0020 | 0.0024 | 0.0022 | 0.0039 | 0.0019 | 0.0019 |
| loss | | | | | | | |
| tangent | | | | | | | |

As can be seen from Table 1, when a resin composition containing the radical-polymerizable compound (A) and the phosphoric acid ester compound (B) is used (Examples 1 to 8), a cured product excellent in flame retardancy and interlayer adhesion is obtained while maintaining a low relative dielectric constant, a low dielectric loss tangent, and a high glass transition temperature as compared with the case where the resin composition is not used (Comparative Examples 1 to 7). Regarding the glass transition temperature, comparison between Examples and Comparative Examples in which the content of the compatible phosphorus compound is the same (specifically, comparison of Examples 1 and 3 with Comparative Examples 1 and 3, and comparison of Examples 2 and 4 to 6 with Comparative Examples 2, 4, 6, and 7) shows that Examples 1 to 8 have a higher glass transition temperature than Comparative Examples 1 to 6.

This application is based on Japanese Patent Application No. 2021-095998 filed on Jun. 8, 2021, the contents of which are included in the present application.

In order to express the present invention, the present invention has been described above appropriately and sufficiently through the embodiments. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

The present invention provides a resin composition, which affords a cured product having a low relative dielectric constant and a low dielectric loss tangent, being excellent in flame retardancy and interlayer adhesion, and having a high glass transition temperature. In addition, the present invention provides a prepreg, a film with resin, a metal foil with resin, a metal-clad laminate, and a wiring board which are obtained using the resin composition.

1. A resin composition comprising:
a radical-polymerizable compound (A) having a carbon-carbon unsaturated double bond in a molecule; and
a phosphoric acid ester compound (B) having an alicyclic hydrocarbon structure in a molecule.

2. The resin composition according to claim 1, wherein
the phosphoric acid ester compound (B) has at least one structure represented by the following Formula (1) in a molecule: 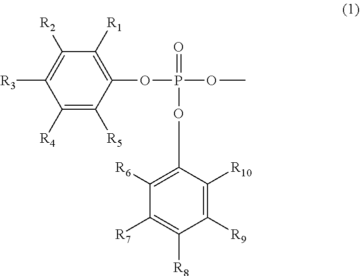
wherein, in Formula (1), R₁ to R₁₀ each independently represent a hydrogen atom, an alkyl group, an alkenyl group, an alkynyl group, a formyl group, an alkylcarbonyl group, an alkenylcarbonyl group, or an alkynylcarbonyl group.

3. The resin composition according to claim 1, wherein the alicyclic hydrocarbon structure includes a 3 to 12 membered saturated alicyclic hydrocarbon structure.

4. The resin composition according to claim 1, wherein
the phosphoric acid ester compound (B) includes a phosphoric acid ester compound represented by the following Formula (2): 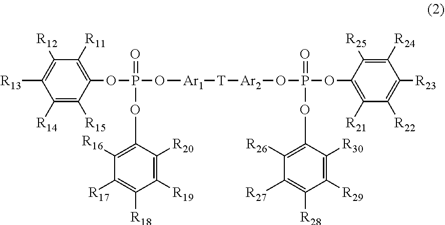
wherein, in Formula (2), R₁₁ to R₃₀ each independently represent a hydrogen atom, an alkyl group, an alkenyl group, an alkynyl group, a formyl group, an alkylcarbonyl group, an alkenylcarbonyl group, or an alkynylcarbonyl group, Ar₁ and Ar₂ each independently represent an arylene group, and T represents a divalent group of a 3 to 12 membered saturated alicyclic hydrocarbon.

5. The resin composition according to claim 1, wherein a content of the phosphoric acid ester compound (B) is 5 to 60 parts by mass with respect to 100 parts by mass of the radical-polymerizable compound (A).

6. The resin composition according to claim 1, further comprising a non-compatible phosphorus compound (C) that is not compatible with the radical-polymerizable compound (A).

7. The resin composition according to claim 6, wherein the non-compatible phosphorus compound (C) includes at least one selected from the group consisting of a phosphine oxide compound, a phosphinate compound, a polyphosphoric acid ester compound, and a phosphonium salt compound.

8. The resin composition according to claim 6, wherein a content of the phosphoric acid ester compound (B) is 10 to 70% by mass with respect to a total mass of the phosphoric acid ester compound (B) and the non-compatible phosphorus compound (C).

9. The resin composition according to claim 1, wherein the radical-polymerizable compound (A) includes at least one selected from the group consisting of a polyphenylene ether compound having a carbon-carbon unsaturated double bond in a molecule, a polyfunctional aromatic vinyl compound, an allyl compound, a polyfunctional methacrylate compound, a polyfunctional acrylate compound, a polybutadiene compound, an acenaphthylene compound, and a styrene compound.

10. The resin composition according to claim 9, wherein
the polyphenylene ether compound includes a polyphenylene ether compound having at least one of a group represented by the following Formula (3) and a group represented by the following Formula (4) in a molecule: 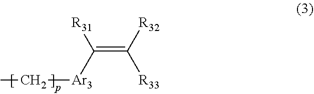
wherein, in Formula (3), p represents 0 to 10, Ar₃ represents an arylene group, and R₃₁ to R₃₃ each independently represent a hydrogen atom or an alkyl group, 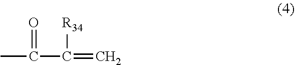
wherein, in Formula (4), R₃₄ represents a hydrogen atom or an alkyl group.

11. The resin composition according to claim 1, further comprising a styrenic copolymer.

12. A prepreg comprising:
the resin composition according to claim 1 or a semi-cured product of the resin composition; and
a fibrous base material.

13. A film with resin comprising:
a resin layer containing the resin composition according to claim 1 or a semi-cured product of the resin composition; and
a support film.

14. A metal foil with resin comprising:
a resin layer containing the resin composition according to claim 1 or a semi-cured product of the resin composition; and
a metal foil.

15. A metal-clad laminate comprising:
an insulating layer containing a cured product of the resin composition according to claim 1; and
a metal foil.

16. A wiring board comprising:
an insulating layer containing a cured product of the resin composition according to claim 1; and
a wiring.

17. A metal-clad laminate comprising:
an insulating layer containing a cured product of the prepreg according to claim 12; and
a metal foil.

18. A wiring board comprising:
an insulating layer containing a cured product of the prepreg according to claim 12; and
a wiring.
